(19) United States
(12) Patent Application Publication
(10) Pub. No.: US 2025/0372404 A1
(43) Pub. Date: Dec. 4, 2025

(54) DISPLAY DEVICE, ELECTRONIC DEVICE INCLUDING DISPLAY DEVICE, AND APPARATUS AND METHOD FOR PROVIDING THE SAME

(71) Applicant: Samsung Display Co., Ltd., Yongin-si (KR)

(72) Inventors: TAEWOO PARK, Yongin-si (KR); JEONGWEON SEO, Yongin-si (KR); GWANGTAEK LEE, Yongin-si (KR); JEONGHO HWANG, Yongin-si (KR)

(21) Appl. No.: 19/050,213

(22) Filed: Feb. 11, 2025

(30) Foreign Application Priority Data
May 28, 2024 (KR) 10-2024-0069511

(51) Int. Cl. H01L 21/56; H01L 21/687

(52) U.S. Cl. CPC H01L 21/56; H01L 21/68721

(57) ABSTRACT

A method for providing an electronic device includes providing a substrate of a display device which includes a top surface, a bottom surface and an outer side surface, providing a support frame to surround the substrate, the support frame including a top surface inclined at an angle with respect to the top surface of the substrate, providing a resin material which is on the top surface of the substrate and extends from the top surface of the substrate and along the first sub-surface of the support frame to define a preliminary resin layer on the substrate, providing heat from the support frame to the preliminary resin layer on the substrate, curing the preliminary resin layer on the substrate to form a resin layer of the display device which is on the substrate, and separating the support frame from the substrate having the resin layer thereon.

This patent application claims priority Korean Patent Application No. 10-2024-0069511, filed on May 28, 2024, and all the benefits accruing therefrom under 35 U.S.C. § 119, the entire contents of which are hereby incorporated by reference.

### BACKGROUND

### (1) Field

The present disclosure herein relates to a display device, an apparatus and method for manufacturing (or providing) the display device, and an electronic device including the display device.

### (2) Description of the Related Art

Various types of display devices of an electronic device are used to provide image information. Each of the display devices may be divided into a display area corresponding to an active area and a non-display area on which a controller such as a circuit board for controlling the active area is disposed.

A structure of a flexible display device which minimizes or bends the non-display area to improve visibility and reduce a dead space has been proposed. There is a demand for improving reliability of an adhesion member used to bond components of the display device to each other so that the display device has good durability even when the dead space is reduced.

### SUMMARY

The present disclosure provides a display device, an apparatus and method for manufacturing (or providing) the display device having improved process efficiency and reliability, and an electronic device including the display device.

An embodiment of the invention provides a method for manufacturing (or providing) a display device, the method including preparing a substrate including a top surface defined by a first direction and a second direction crossing the first direction and a bottom surface facing the top surface, preparing a support disposed to surround an edge of the substrate and including a first sub-surface which is inclined at a predetermined angle with respect to the top surface of the substrate, forming a preliminary resin layer of which at least a portion is in contact with the first sub-surface by applying a resin composition onto the substrate, providing heat from the support to the preliminary resin layer, curing the preliminary resin layer to form a resin layer, and separating the support from the substrate on which the resin layer is formed.

In an embodiment, the support may include a first portion disposed adjacent to the substrate and including the first sub-surface, and a second portion disposed to be spaced apart from the substrate with the first portion therebetween and including a second sub-surface parallel to the top surface of the substrate.

In an embodiment, the first portion and the second portion may have an integrated shape.

In an embodiment, the support may include an inner surface extending from the first sub-surface and parallel to a third direction crossing the first direction and the second direction, an opening may be defined in the support by the inner surface, and the substrate may be disposed within the opening.

In an embodiment, the inner surface of the support may be in contact with the substrate.

In an embodiment, in the providing of the heat to the preliminary resin layer, at least a portion of a portion of the preliminary resin layer, which is in contact with the first sub-surface, may move from the first sub-surface toward a central portion of the substrate.

In an embodiment, when before the providing of the heat to the preliminary resin layer, an area on which the preliminary resin layer is in contact with the first sub-surface is defined as a first area, and after the providing of the heat to the preliminary resin layer, an area on which the preliminary resin layer is in contact with the first sub-surface is defined as a second area, the second area may be less than the first area.

In an embodiment, the first sub-surface may be inclined at a first angle with respect to the top surface, where the first angle may be greater than or equal to about 20 degrees and less than or equal to about 85 degrees.

In an embodiment, the support may include a hydrophobic material.

In an embodiment, the support may include a metal material, and at least the first sub-surface is hydrophobic-treated.

In an embodiment, the support may include a first portion including the first sub-surface, a second portion disposed outside the first portion and including a second sub-surface parallel to the top surface of the substrate, and a third portion disposed between the first portion and the substrate and including a third sub-surface parallel to the top surface of the substrate.

In an embodiment, in the forming of the preliminary resin layer, the preliminary resin layer may be in contact with each of the first sub-surface and the third sub-surface.

In an embodiment, at least the first sub-surface and the third sub-surface of the support may be hydrophobic-treated.

In an embodiment, the support may include an inner surface extending from the third sub-surface and parallel to a third direction crossing the first direction and the second direction, and the substrate may be in contact with the inner surface.

In an embodiment, the third sub-surface may be disposed on the same line as the top surface of the substrate.

In an embodiment, the substrate may include a plurality of side surfaces which connects the top surface to the bottom surface, where the plurality of side surface may include a first side surface and a second side surface, which face each other in the first direction, and a third side surface and a fourth side surface, which face each other in the second direction, where the support may include a first sub-support which is in contact with the first side surface, a second sub-support which is in contact with the second side surface, a third sub-support which is in contact with the third side surface, and a fourth sub-support which is in contact with the fourth side surface, where the first to fourth sub-supports may be connected to each other to define an opening in the substrate is disposed.

In an embodiment, each of the first to fourth sub-supports may include a first portion disposed adjacent to the substrate and including the first sub-surface, and a second portion disposed to be spaced apart from the substrate with the first portion therebetween and including a second sub-surface parallel to the top surface of the substrate.

In an embodiment of the invention, a method for manufacturing a display device includes preparing a substrate, a preparing a support disposed to be in contact with a side surface of the substrate and including an inclined part which gradually decreases in thickness toward the outside, forming a preliminary resin layer of which at least a portion is disposed on the inclined part by applying a resin composition onto the substrate, providing heat from the support to the preliminary resin layer, curing the preliminary resin layer to form a resin layer, and separating the substrate, on which the resin layer is formed, from the support.

In an embodiment, the support may further include a flat part disposed between the substrate and the inclined part and having a constant thickness, where a top surface of the flat part may be disposed on the same line as the top surface of the substrate.

In an embodiment of the invention, an apparatus for manufacturing a display device includes a stage on which a substrate is provided, a support in which an opening, in which the substrate is disposed, is defined and which includes an inclined part having a thickness which gradually increases toward the outside, and a heater configured to provide heat to the support.

### BRIEF DESCRIPTION OF THE FIGURES

The accompanying drawings are included to provide a further understanding of the invention, and are incorporated in and constitute a part of this specification. The drawings illustrate embodiments of the invention and, together with the description, serve to explain principles of the invention. In the drawings:

FIG. 1 is a perspective view of a display device according to an embodiment of the invention;

FIG. 2 is an exploded perspective view of the display device according to an embodiment of the invention;

FIG. 3 is a cross-sectional view illustrating some of constituents of the display device according to an embodiment of the invention;

FIG. 4A is across-sectional view of a display device according to an embodiment of the invention;

FIG. 4B is a cross-sectional view of a display device according to an embodiment of the invention;

FIGS. 5A to 5C are schematic views illustrating an apparatus for manufacturing a display device according to an embodiment of the invention;

FIGS. 6A and 6B are plan views illustrating some of constitutes of the apparatus for manufacturing the display device according to an embodiment of the invention;

FIGS. 7A and 7B are schematic views illustrating the apparatus for manufacturing the display device according to an embodiment of the invention;

FIG. 8 is a flowchart illustrating a method for manufacturing a display device according to an embodiment of the invention;

FIGS. 9A to 9G are schematic views illustrating a process of manufacturing a resin layer AP according to an embodiment of the invention;

FIG. 10 is a cross-sectional view for explaining limitations which may occur in the display device;

FIGS. 11A to 11C are cross-sectional views illustrating the method for manufacturing the display device according to an embodiment of the invention.

FIG. 12 is a block diagram illustrating an electronic device according to an embodiment of the present disclosure; and

FIG. 13 is a schematic view of electronic devices according to embodiments of the present disclosure.

### DETAILED DESCRIPTION

Hereinafter, embodiments of the invention will be described with reference to the accompanying drawings.

In this specification, it will also be understood that when one component (or region, layer, portion, etc.) is referred to as being related to another element such as being ‘on’, ‘connected to’, or ‘coupled to’ another component, it can be directly connected/coupled on/to the one component, or an intervening third component may also be present. When one component (or region, layer, portion, etc.) is referred to as being related to another element such as being ‘directly on’, ‘directly connected to’, or ‘directly coupled to’ another component, no intervening third component is present.

Like reference numerals refer to like elements throughout. Also, in the figures, the thickness, ratio, and dimensions of components are exaggerated for clarity of illustration.

The terminology used herein is for the purpose of describing particular embodiments only and is not intended to be limiting. As used herein, “a”, “an,” “the,” and “at least one” do not denote a limitation of quantity, and are intended to include both the singular and plural, unless the context clearly indicates otherwise. Thus, reference to “an” element in a claim followed by reference to “the” element is inclusive of one element and a plurality of the elements. For example, “an element” has the same meaning as “at least one element,” unless the context clearly indicates otherwise. “At least one” is not to be construed as limiting “a” or “an.” “Or” means “and/or.” The term “and/or” includes any and all combinations of one or more of the associated listed items.

It will be understood that although the terms such as ‘first’ and ‘second’ are used herein to describe various elements, these elements should not be limited by these terms. The terms are only used to distinguish one component from other components. For example, a first element referred to as a first element in an embodiment can be referred to as a second element in another embodiment without departing from the scope of the appended claims. The terms of a singular form may include plural forms unless referred to the contrary.

Also, “under”, “below”, “above', “upper”, and the like are used for explaining relation association of components illustrated in the drawings. The terms may be a relative concept and described based on directions expressed in the drawings.

The meaning of ‘include’ or ‘comprise’ specifies a property, a fixed number, a step, an operation, an element, a component or a combination thereof, but does not exclude other properties, fixed numbers, steps, operations, elements, components or combinations thereof.

In this specification, “directly disposed” may mean that there is no layer, film, region, plate, or the like between a portion of the layer, the layer, the region, the plate, or the like and the other portion. For example, “directly disposed” may mean being disposed without using an additional member such and an adhesion member between two layers or two members.

“About” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” can mean within one or more standard deviations, or within ±30%, 20%, 10% or 5% of the stated value.

Unless otherwise defined, all terms (including technical and scientific terms) used herein have the same meaning as commonly understood by a person of ordinary skill in the art to which this invention belongs. In addition, terms such as those defined in commonly used dictionaries should be interpreted as having meanings consistent with their meanings in the context of the relevant technology, and unless explicitly defined, it should not be interpreted in an overly idealistic or overly formal sense.

Hereinafter, a display device DD and an apparatus and method for manufacturing (or providing) the display device DD according to an embodiment of the invention will be described with reference to the accompanying drawings.

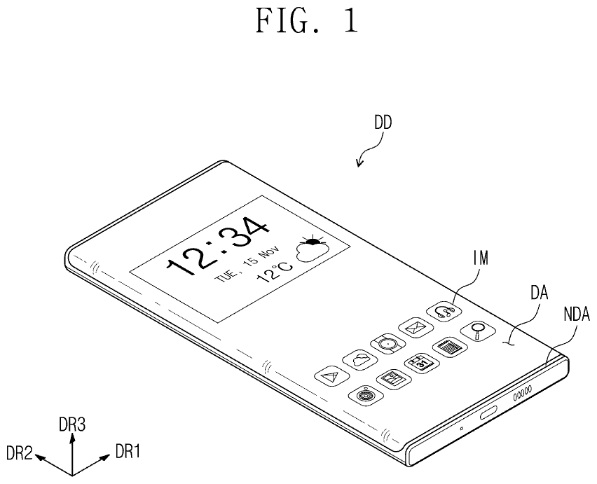

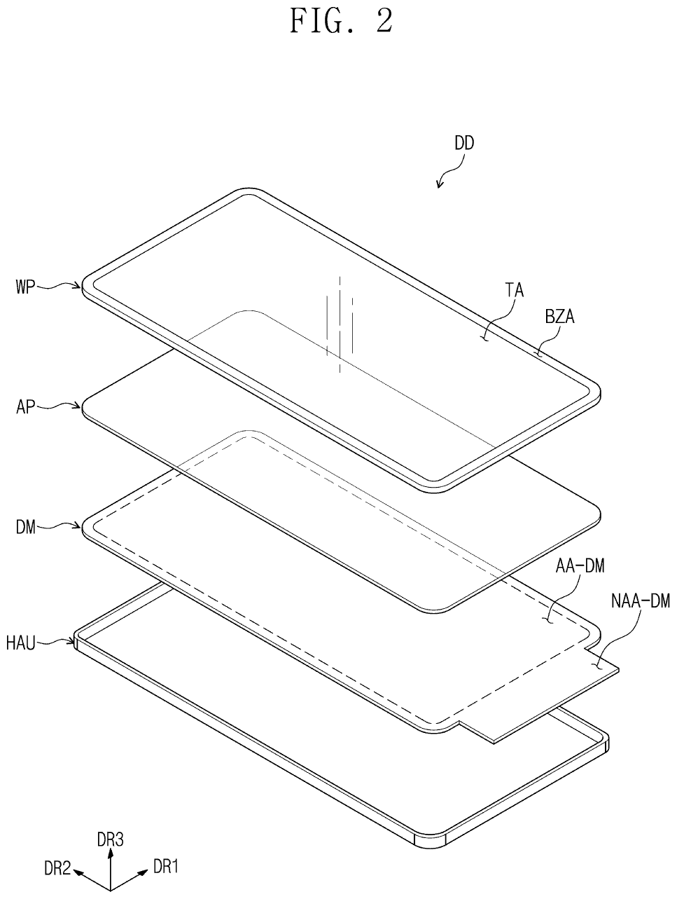

FIG. 1 is a perspective view of a display device DD according to an embodiment of the invention. FIG. 2 is an exploded perspective view of the display device DD according to an embodiment of the invention.

A display device DD illustrated in FIG. 1 according to an embodiment may be a device (e.g., an electronic device) activated according to an electrical signal. For example, the display device DD may be a personal computer, a notebook computer, a personal digital assistant, a game console, a portable electronic device, a television, a monitor, an outdoor billboard, an automobile navigation system, or a wearable device, but this embodiment is not limited thereto. In FIG. 1, a mobile phone may be provided as an example of the display device DD.

The display device DD according to an embodiment may display an image IM through a display area DA. The display area DA may be disposed in or parallel to a plane defined by a first direction DR1 and a second direction DR2 which cross each other. The display area DA may include a curved surface which is bent from at least one side of a planar area defined by the first direction DR1 and the second direction DR2. The display device DD illustrated in FIG. 1 according to an embodiment may be illustrated as including two curved surfaces which are bent from each of opposing side surfaces of the planar area defined by the first direction DR1 and the second direction DR2, respectively. However, a planar shape and a three-dimensional shape of the display area DA may not be limited thereto. For example, the display area DA may include only the planar area defined by the first direction DR1 and the second direction DR2, or the display area DA may further include four curved surfaces which are bent from at least two or more, for example, four side surfaces, of the planar area defined by the first direction DR1 and the second direction DR2, respectively.

The display device DD according to an embodiment may be flexible. The “flexible” means a bendable property and may include anything from a completely foldable structure to a structure which is capable of bend at a level of a few nanometers. For example, the display device DD may be a foldable display device. Also, the display device DD may be rigid.

The non-display area NDA may be an area adjacent to the display area DA. The non-display area NDA may surround the display area DA in a plan view. Thus, the shape of the display area DA may be substantially defined by the non-display area NDA. However, the embodiment of the invention is merely an example. For example, the non-display area NDA may be disposed adjacent to only one side of the display area DA or may be omitted. The display area DA may be provided in various shapes and is not limited to any an embodiment.

In FIG. 1 and following drawings, first to third direction DR1 to DR3 are illustrated, and directions indicated by the first to third direction DR1, DR2, and DR3, which are described in this specification, may be converted to other directions as a relative concept. In this specification, the first direction DR1 and the second direction DR2 may be perpendicular to each other. A third direction DR3 may be a normal direction with respect to a plane defined by the first direction DR1 and the second direction DR2 which cross each other.

A thickness direction of the display device DD may be a direction which is parallel to the third direction DR3, which is the normal direction to the plane defined by the first direction DR1 and the second direction DR2. In this specification, a front surface (or top surface, upper surface, and upper side) and a rear surface (or bottom surface, lower surface, and lower side) of each of members constituting the display device DD may be defined based on a third direction DR3. In addition, in this specification, a direction in which the third direction DR3 extends may be parallel to a thickness direction, the front surface (or top surface, upper surface, and upper side) may mean a surface (or direction) adjacent to a surface on which an image IM is displayed, and the rear surface (or bottom surface, lower surface, and lower side) may mean a surface (or direction) spaced from the surface on which the image IM is displayed.

Referring to FIG. 2, the display device DD may include a display module DM, a window WP disposed on the display module DM, and a resin layer AP disposed between the display module DM and the window WP. In addition, the display device DD may further include a housing HAU in which the display module DM is accommodated.

In the display device DD illustrated in FIGS. 1 and 2, the window WP and the housing HAU may be coupled to each other to define an outer appearance of the display device DD. The housing HAU may be disposed at a lower side of the display module DM. The housing HAU may include a material having relatively high rigidity. For example, the housing HAU may include a plurality of frames and/or plates made of glass, plastic, or a metal. The housing HAU may provide a predetermined accommodation space. The display module DM may be accommodated within the accommodation space and protected from an external impact.

The display module DM may be activated by an electrical signal. The display module DM may be activated to display the image IM (see FIG. 1) at the display area DA (FIG. 1) of the display device DD. The display module DM may define an active area AA-DM and a peripheral area NAA-DM. The active area AA-DM may be a planar area which is activated according to an electrical signal. The peripheral area NAA-DM may be a planar area disposed adjacent to at least one side of the active area AA-DM. A circuit or line for driving the active area AA-DM may be disposed on the peripheral area NAA-DM.

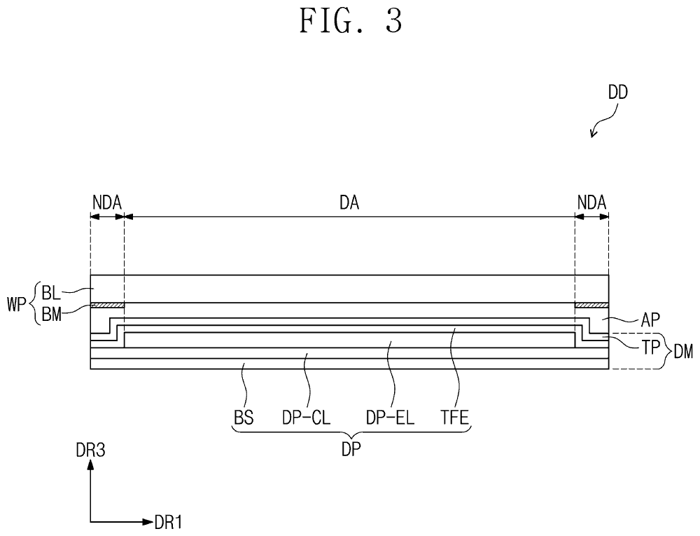

The resin layer AP may be disposed on the display module DM. The resin layer AP may be configured to bond the display module DM to at least two of functional layers disposed on the display module DM. Alternatively, the resin layer AP may be a composition which bonds at least two of the functional layers included in the display module DM. For example, the resin layer AP may be disposed between the display module DM and the window WP to bond the display module DM to the window WP. However, the embodiment of the invention is not limited thereto. In the display device DD according to an embodiment, the resin layer AP may form a base layer BL (see FIG. 3) of the window WP. In this case, the window WP may be disposed directly on the display module DM. The resin layer AP according to an embodiment may be formed (or provided) through a method for manufacturing (or providing) a display device DD according to an embodiment, which will be described below. This will be explained in detail later.

The resin layer AP may include a common adhesive or adhesion agent. The resin layer AP may be an optically clear adhesive film (OCA) or an optically clear adhesive resin layer (OCR).

The window WP may include a transmission area TA and a bezel area BZA. The transmission area TA may overlap at least a portion of the active area AA-DM of the display module DM. The transmission area TA may be an optically transparent area. The image IM (see FIG. 1) may be provided to outside the display device DD, such as to a user, through the transmission area TA.

The bezel area BZA may be an area (e.g., a planar area) having light transmittance which is relatively less than a light transmittance of the transmission area TA. The bezel area BZA may define a planar shape of the transmission area TA. The bezel area BZA may be disposed adjacent to the transmission area TA to surround the transmission area TA. With respect to the display area DA and the non-display area NDA, the transmission area TA and the bezel area BZA, the active area AA-DM and the peripheral area NAA-DM, etc., a boundary may be defined where two respective areas meet.

The bezel area BZA may have a predetermined color. The bezel area BZA may cover a peripheral area NAA-DM of the display module DM to prevent the peripheral area NAA-DM from being visible from the outside. However, the embodiment is not limited as being illustrated, and the bezel area BZA may be disposed adjacent to only one side of the transmission area TA, or at least a portion of the bezel area BZA may be omitted.

FIG. 3 is a cross-sectional view illustrating some of constituents of the display device DD according to an embodiment of the invention. FIG. 3 illustrates the display module DM, the resin layer AP, and the window WP in the display device DD of FIG. 2.

Referring to FIG. 3, the display module DM may include a display panel DP and an input detection part TP which is disposed on the display panel DP. The display panel DP may include a base substrate BS, a circuit layer DP-CL disposed on the base substrate BS, a display element layer DP-EL disposed on the circuit layer DP-CL, and an encapsulation layer TFE covering the display element layer DP-EL. The resin layer AP may be disposed between the display panel DP and the window WP and couple the display panel DP and the window WP to each other.

The configuration of the display panel DP illustrated in FIG. 3 may be merely an example, and thus, the configuration of the display panel DP is not limited thereto. For example, the display panel DP may include a liquid crystal display element. In this case, the encapsulation layer TFE may be omitted.

The base substrate BS may provide a base surface on which the circuit layer DP-CL is disposed. The base substrate BS may be a flexible substrate which is bendable, foldable, rollable, etc. The base substrate BS may be a glass substrate, a metal substrate, or a polymer substrate. However, this embodiment is not limited thereto, and the base substrate BS may include an inorganic layer, an organic layer, or a composite material layer.

The circuit layer DP-CL may include an insulating layer, a semiconductor pattern, a conductive pattern, and a signal line. For example, the circuit layer DP-CL may include a switching transistor and a driving transistor for driving a light emitting element (not shown) of the display element layer DP-EL.

The display element layer DP-EL may include the light emitting element (not shown) which emits light. The light emitting element (not shown) may include an organic light emitting material, an inorganic light emitting material, an organic-inorganic light emitting material, a quantum dot, a quantum rod, a micro LED, or a nano LED. The display element layer DP-EL may connected (e.g., electrically) to the circuit layer DP-CL. The circuit layer DP-CL may drive and/or control the display element layer DP-EL to generate or emit light, to display an image IM, etc., without being limited thereto.

The encapsulation layer TFE may be disposed above the display element layer DP-EL. The encapsulation layer TFE may protect the display element layer DP-EL against foreign substances such as moisture, oxygen, and/or dust particles. The encapsulation layer TFE may include at least one inorganic layer. The encapsulation layer TFE may include at least one organic layer and at least one inorganic layer. For example, the encapsulation layer TFE may include an inorganic layer, an organic layer, and an inorganic layer, which are sequentially laminated.

The input detection part TP as an input sensing layer may be disposed on the display panel DP. For example, the input detection part TP may be disposed directly on the encapsulation layer TFE of the display panel DP. The input detection part TP may detect an external input, change the external input into a predetermined input signal, and provide the input signal to the display panel DP. For example, in the display device DD according to an embodiment, the input detection part TP may be a touch detection part which detects a touch as an external input to the display device DD by an input tool. The input detection part TP may recognize a direct touch (e.g., a physical contact) of the input tool such as a body part of a user, an indirect touch (e.g., a hovering or proximity) of the body part of the user, a direct touch of an object (e.g., a pen, etc.) as the input tool, or an indirect touch of the object as an input tool. The external input may also include light, pressure, etc., without being limited thereto.

The input detection part TP may detect at least one of a position or intensity (a pressure) of touch applied from the outside (e.g., the outside of the input sensing layer and/or the display device DD). In an embodiment, the input detection part TP may have various structures or be made of various materials, but is not limited to any one embodiment. The input detection part TP may include a plurality of detection electrodes (not shown) for detecting an external input. The detection electrodes (not shown) may detect an external input in a capacitive manner. The display panel DP may receive the input signal from the input detection part TP to generate an image IM corresponding to the input signal.

The window WP may include a base layer BL and a printed layer BM. Although not shown, the window WP may further include at least one functional layer (not shown) provided on the base layer BL. For example, the functional layer (not shown) may be a hard coating layer, an anti-fingerprint coating layer, etc., but this embodiment is not limited thereto.

The base layer BL may be a glass substrate. Alternatively, the base layer BL may be a plastic substrate. For example, the base layer BL may be made of (or include) polyimide, polyacrylate, polymethylmethacrylate, polycarbonate, polyethylenenaphthalate, polyvinylidene chloride, polyvinylidene difluoride, polystyrene, an ethylene vinylalcohol copolymer, or a combination thereof.

The printed layer BM may be disposed on one surface of the base layer BL. The printed layer BM may be provided on a bottom surface of the base layer BL adjacent to the display module DM. The printed layer BM may be disposed on an edge area of the base layer BL, in a direction along the DR1-DR2 plane. The printed layer BM may be an ink-printed layer. Additionally, the printed layer BM may be a layer formed (or provided) by including a pigment or a dye. In the window WP, the bezel area BZA may be a portion at which the printed layer BM is provided. The printed layer BM may be a light blocking pattern or layer.

The window WP may further include at least one functional layer (not shown) provided on the base layer BL. For example, the functional layer (not shown) may be a hard coating layer, an anti-fingerprint coating layer, etc., but this embodiment is not limited thereto.

In FIG. 3, the resin layer AP is illustrated as being disposed between the window WP and the display module DM, but the embodiment is not limited thereto. Unlike as illustrated in FIG. 3, the resin layer AP may constitute the base layer BL of the window WP. In this case, the window WP may be disposed directly on the display module DM.

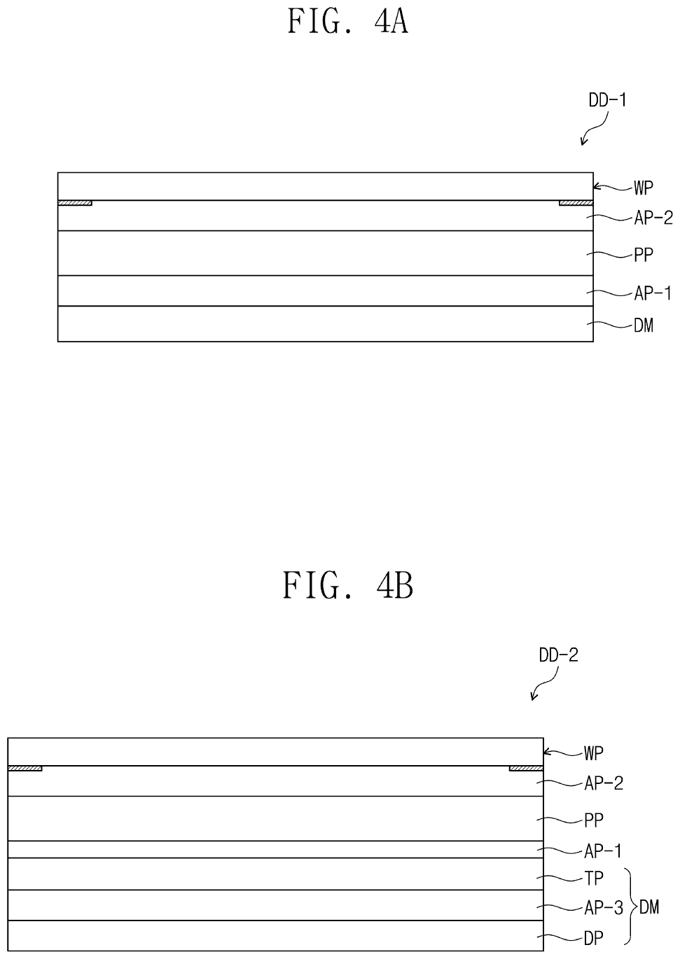

FIG. 4A is a cross-sectional view of a display device DD-1 according to an embodiment of the invention. In the description of the display device DD-1 with reference to FIG. 4A, contents duplicated with those described with reference to FIGS. 1 to 3 will be omitted, and thus, their differences will be mainly described.

The display device DD-1 illustrated in FIG. 4A according to an embodiment may further include a light control layer PP. The display device DD-1 according to an embodiment may include the light control layer PP disposed between the display module DM and the window WP and also may include a first resin layer AP-1 disposed between the display module DM and the light control layer PP and a second resin layer AP-2 disposed between the light control layer PP and the window WP.

The light control layer PP may be disposed on the display panel DP to control external light reflected from the display panel DP. The light control layer PP may include, for example, a polarizing layer and/or a color filter layer.

Each of the first resin layer AP-1 and the second resin layer AP-2 may be an optically clear adhesive film (OCA) or an optically clear adhesive resin layer (OCR). At least one of the first resin layer AP-1 and the second resin layer AP-2 may be provided through the method for manufacturing (or providing) the display device DD-1 according to an embodiment in the same manner as the resin layer AP according to the foregoing embodiment.

FIG. 4B is a cross-sectional view of a display device DD-2 according to an embodiment of the invention. In the description of the display device with reference to FIG. 4B, contents duplicated with those described with reference to FIGS. 1 to 4A will be omitted, and thus, their differences will be mainly described.

The display device DD-2 illustrated in FIG. 4B according to an embodiment may further include a third resin layer AP-3 disposed between the display panel DP and the input detection part TP.

The display device DD-2 according to an embodiment may include a display module DM, a window WP disposed on the display module DM, and a light control layer PP disposed between the display module DM and the window WP, like the display device DD-1 illustrated in FIG. 4A according to an embodiment. In addition, the display device DD-2 according to an embodiment may include a first resin layer AP-1 disposed between the display module DM and the light control layer PP and a second resin layer AP-2 disposed between the light control layer PP and the window WP.

The display device DD-2 according to an embodiment may further include a third resin layer AP-3 disposed between the display panel DP and the input detection part TP. That is, the input detection part TP may not be directly disposed on the display panel DP, but the display panel DP and the input detection part TP may be bonded to each other by the third resin layer AP-3. For example, the third resin layer AP-3 may be disposed between the encapsulation layer TFE (see FIG. 3) of the display panel DP and the input detection part TP.

Each of the first to third resin layers AP-1, AP-2, and AP-3 may be an optically clear adhesive film OCA or an optically clear adhesive resin layer OCR. At least one of the first to third resin layers AP-1, AP-2, and AP-3 may be formed through the method for manufacturing the display device according to an embodiment in the same manner as the resin layer AP according to the foregoing embodiment.

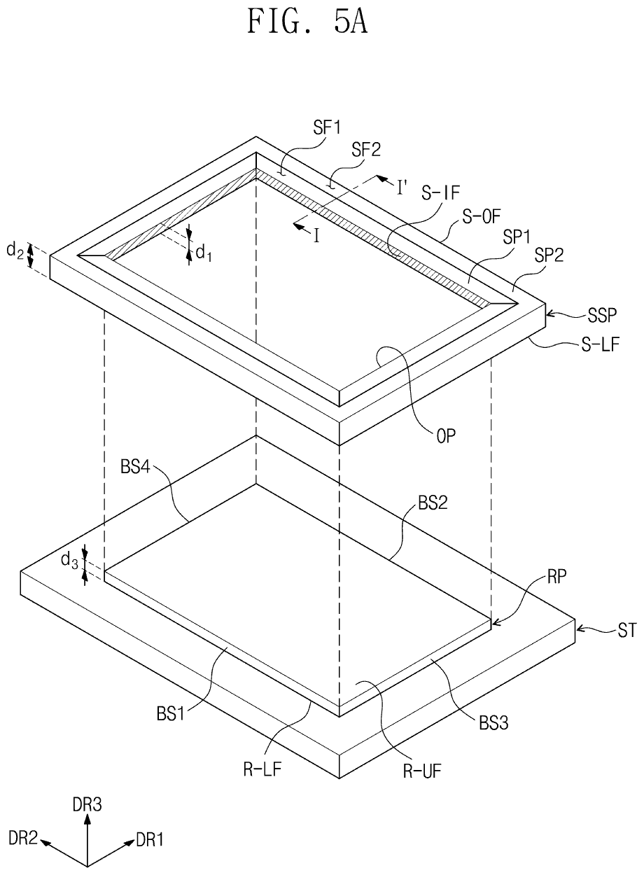

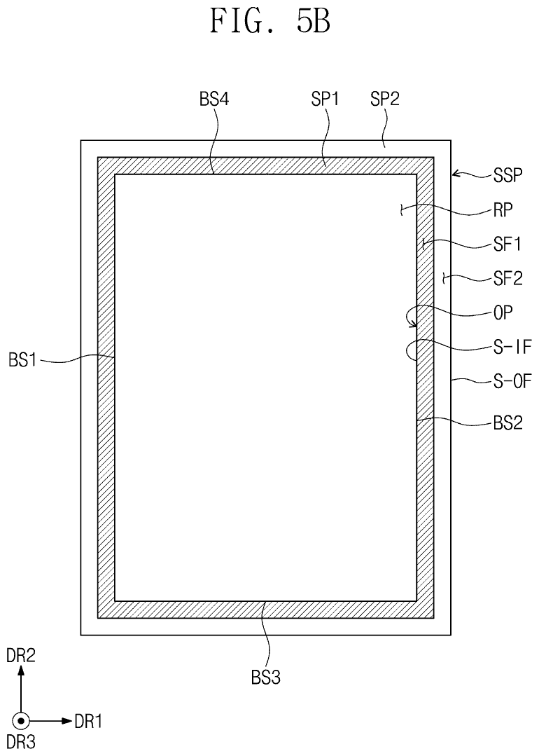

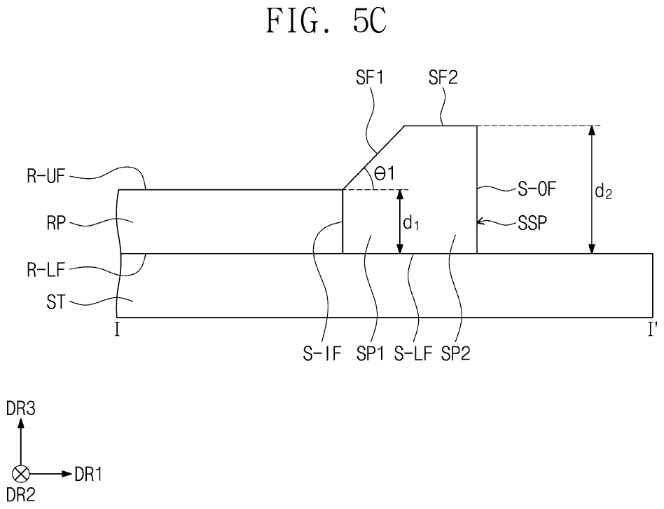

FIGS. 5A to 5C are schematic views illustrating an apparatus for manufacturing (or providing) a display device DD according to an embodiment of the invention. FIG. 5A is a perspective view illustrating the apparatus for manufacturing the display device DD according to an embodiment of the invention. FIG. 5B is a plan view illustrating the apparatus for manufacturing the display device DD illustrated in FIG. 5A as viewed from above. FIG. 5C is a cross-sectional view taken along line I-I′ of FIG. 5A.

In FIGS. 5A to 5C, a substrate RP, which is an object to be processed, is illustrated together with the apparatus for manufacturing the display device DD. The substrate RP may include an outer edge.

Referring to FIGS. 5A to 5C, the apparatus for manufacturing the display device DD according to an embodiment of the invention includes a stage ST, a support SSP, and a heater (not shown).

The stage ST may provide a space in which the substrate RP is seated. The stage ST may be provided in the form of a plate. In FIG. 5A, the stage ST is illustrated as being square on a plane, but this embodiment is not limited thereto, and a shape and size of the stage ST on the plane may be changed in various manners. The object to be processed may be supported on the stage ST.

The heater (not shown) may provide heat to the support SSP. A variety of heating devices may be used as the heater (not shown). For example, the heater (not shown) may include a current heating device, an electric heater, etc. The current heating device may be provided as an electric circuit that may heat the support by generating heat when predetermined current is applied.

The heater (not shown) may be installed inside the support SSP. However, the heater (not shown) may not necessarily have to be installed inside the support SSP, and the heater (not shown) may be installed in a separate device (not shown) which accommodates and drives the heating device to transfer heat to the support SSP. In this case, the support SSP may be provided on the stage ST after receiving the heat from the heater (not shown). When the heater (not shown) is installed inside the support SSP, the heater (not shown) may be provided with a driving part which may selectively generate heat if necessary. The support SSP as a heated support, may be heatable by a heater as a component of the support SSP and/or by a heater which is connected to the support SSP.

The support SSP may be provided in a square frame shape surrounding an edge of the substrate RP. The support SSP may have an enclosed shape in the plan view. On the plane, the support SSP may be disposed to surround an edge (e.g., the outer edge) of the substrate RP. An opening OP in which the substrate RP is disposed may be defined in (or by) the support SSP. A planar area of the opening OP may be substantially equal to a planar area of the substrate RP. The support SSP includes sides which extend to have a major dimension along the DR1-DR2 plane. For example, the square frame shape includes two side portions extending along the first direction DR1 and two side portions extending along the second direction DR2, where adjacent side portions meet at a corner of the support SSP. Inner corners of the support SSP within the opening OP may correspond to corners of the substrate RP.

The support SSP may include top surfaces SF1 and SF2, a bottom surface S-LF which is opposite to the top surfaces SF1 and SF2, an inner surface S-IF, and an outer surface S-OF which is opposite to the inner surface S-IF. The bottom surface S-LF may be parallel to the plane defined by the first direction DR1 and the second direction DR2. The top surfaces SF1 and SF2 may include a first sub-surface SF1 as a first top sub-surface and a second sub-surface SF2 as a second top sub-surface. The top surface SF1 and SF2 of the support SSP may be respectively defined by the first sub-surface SF1 and the second sub-surface SF2.

Each of the inner surface S-IF and the outer surface S-OF may be a surface extending from the bottom surface S-LF. Each of the inner surface S-IF and the outer surface S-OF may be a surface parallel to the third direction DR3 intersecting the first direction DR1 and the second direction DR2. The inner surface S-IF may connect the bottom surface S-LF to the first sub-surface SF1, and the outer surface S-OF may connect the bottom surface S-LF to the second sub-surface SF2. The inner surface S-IF and the outer surface S-OF may face each other in the first direction DR1 or the second direction DR2, to be opposite to each other.

In an embodiment, a height of the inner surface S-IF may be less than that of the outer surface S-OF. The height of the inner surface S-IF as a total height thereof, may be defined as a first length d1. The first length d1 as a first thickness may be a length from the bottom surface S-LF to the uppermost end of the support SSP at the inner surface S-IF. One end of the inner surface S-IF may be in contact with (or meet) the bottom surface S-LF, and the other end of the inner surface S-IF may be in contact with (or meet) the first sub-surface SF1. The other end of the inner surface S-IF may be the uppermost end of the inner surface S-IF. A height of the outer surface S-OF as a total height may be defined as a second length d2. The second length d2 as a second thickness may be a length from the bottom surface S-LF to the uppermost end of the outer surface S-OF. One end of the outer surface S-OF may be in contact with the bottom surface S-LF, and the other end of the outer surface S-OF may be in contact with the second sub-surface SF2. The other end of the outer surface S-OF may be the uppermost end of the outer surface S-OF.

The inner surface S-IF of the support SSP may define the opening OP in which the substrate RP is disposed. The inner surface S-IF of the support SSP may be disposed adjacent to the substrate RP. The inner surface S-IF may be in contact with the substrate RP. The inner side surface (e.g., the inner surface S-IF) of the support SSP may face the outer side surface of the substrate RP.

The substrate RP may include a top surface R-UF, a bottom surface R-LF, and a plurality of side surfaces BS1, BS2, BS3, and BS4 as an outer side surface connecting the top surface R-UF to the bottom surface R-LF. For example, as illustrated in FIGS. 5A and 5B, the substrate RP may include first to fourth side surfaces BS1, BS2, BS3, and BS4 connecting the top surface R-UF to the bottom surface R-LF. The top surface R-UF and the bottom surface R-LF of the substrate RP may face each other to be opposite to each other in the third direction DR3. The first side surface BS1 and the second side surface BS2 may face each other while being spaced apart from each other in the first direction DR1, and the third side surface BS3 and the fourth side BS4 may face each other while being spaced apart from each other in the second direction DR2. In an embodiment, the support SSP may be in contact with each of the plurality of side surfaces BS1, BS2, BS3, and BS4 included in the substrate RP. The inner side surface of the support SSP may be in contact with the outer side surface of the substrate RP at each of the first to fourth side surfaces BS1, BS2, BS3, and BS4 of the substrate RP. In FIGS. 5A and 5B, the substrate RP illustrated as including four side surfaces BS1, BS2, BS3, and BS4, but this embodiment is not limited thereto.

A thickness of the substrate RP may be defined as a third length d3. The third length d3 as a third thickness may mean a length from the bottom surface R-LF of the substrate RP to the top surface R-UF of the substrate RP based on the third direction DR3. In an embodiment, the first length d1 may be substantially equal to the third length d3. However, the embodiment is not limited thereto, and the first length d1 may be greater than the third length d3.

The first sub-surface SF1 may be an inclined surface which is inclined at a predetermined angle θ1. The first sub-surface SF1 may be inclined at a predetermined angle with respect to the top surface R-UF of the substrate RP. One end of the first sub-surface SF1 may be in contact with the inner surface S-IF, and the other end of the first sub-surface SF1 may be in contact with the second sub-surface SF2. An angle at which the first sub-surface SF1 is inclined may be defined as a first angle θ1. That is, the first sub-surface SF1 may be inclined at a first angle θ1 with respect to the top surface R-UF of the substrate RP. In an embodiment, the first angle θ1 may be greater than or equal to about 20 degrees and less than or equal to about 85 degrees.

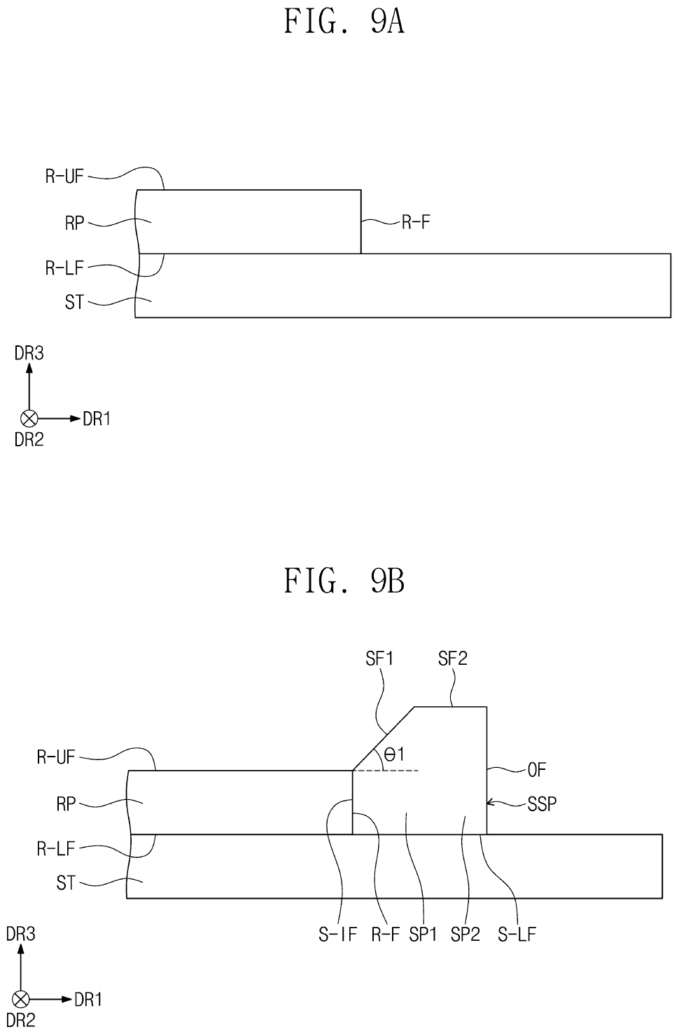

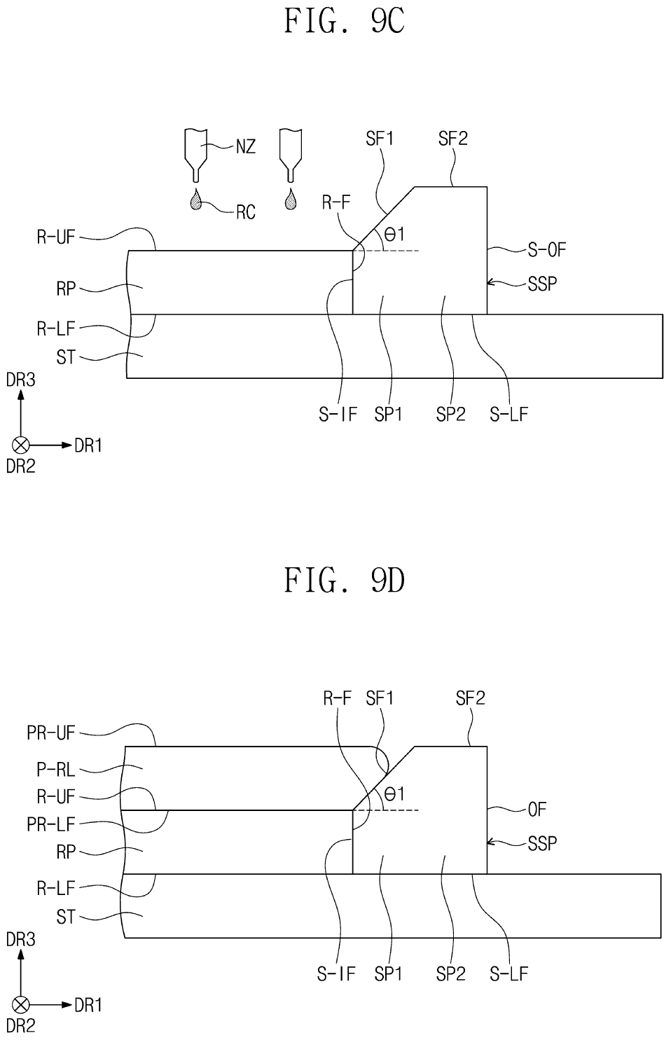

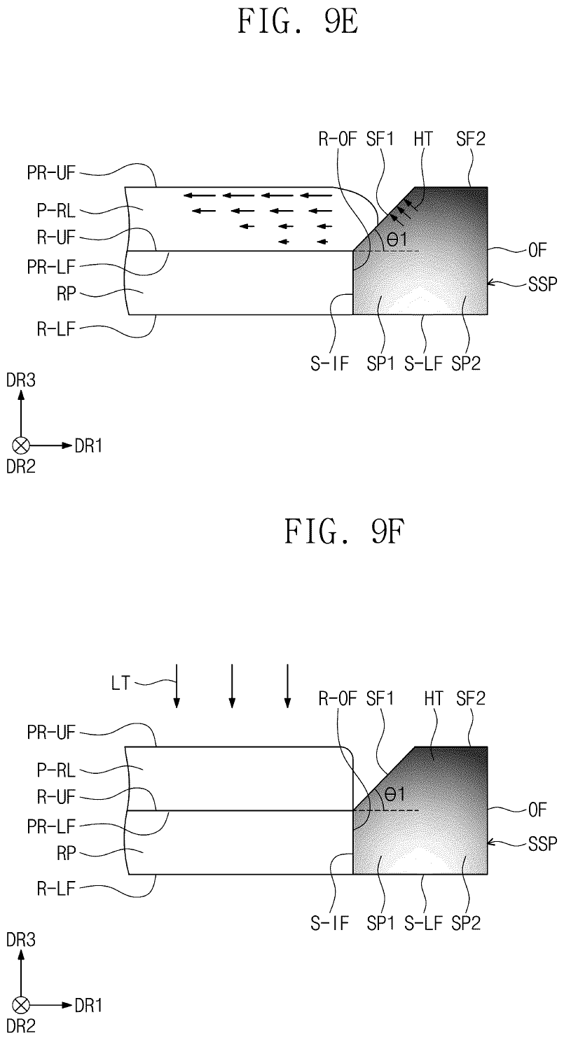

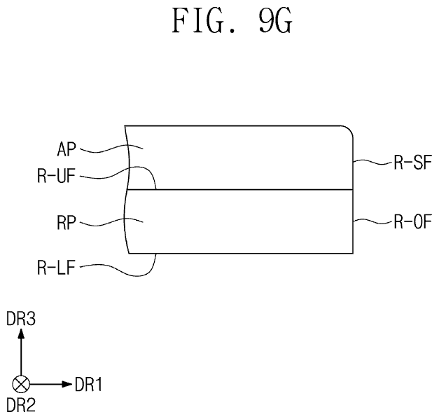

A preliminary stacked structure may include the support SSP assembled on the stage ST, and the substrate RP assembled within the opening OP of the support SSP which is on the stage ST. The preliminary stacked structure may define a volume which is open in the third direction DR3. The volume may be defined by the substrate RP and the inner side surface of the support SSP at the first sub-surface SF1, with or without a portion of the inner surface S-IF. In the state in which the substrate RP disposed within the opening OP, the top surface R-UF and the first sub-surface SF1 of the substrate RP may define an accommodation space (or volume) in which a resin composition RC (see FIG. 9C) described below is provided. The resin composition RC may be processed after being provided in the accommodation space defined by the top surface R-UF of the substrate RP together with the inner side surface of the support SSP, while the substrate RP is disposed within the opening OP. This will be explained in detail later.

The second sub-surface SF2 may define the top surface of the support SSP together with the first sub-surface SF1. The second sub-surface SF2 may be parallel to the plane defined by the first direction DR1 and the second direction DR2. The second sub-surface SF2 may be parallel to the top surface R-UF of the substrate RP. One end of the second sub-surface SF2 may be in contact with the first sub-surface SF1, and the other end of the second sub-surface SF2 may be in contact with the outer surface S-OF.

In the apparatus for manufacturing the display device DD according to an embodiment, the support SSP may include a first portion SP1 as a first thickness portion and a second portion SP2 as a second thickness portion which is closer to the outer edge of the support SSP than the first portion SP1. Inclinations of top surfaces of the first portion SP1 and the second portion SP2 may be different from each other with respect to the plane defined by the first direction DR1 and the second direction DR2. The top surface of the first portion SP1 may include an inclined surface which is inclined at a predetermined angle. The top surface of the second portion SP2 may be parallel to the plane defined by the first direction DR1 and the second direction DR2. The top surface of the first portion SP1 may correspond to the first sub-surface SF1 described above, and the top surface of the second portion SP2 may correspond to the second sub-surface SF2 described above.

On the plane, each of the first portion SP1 and the second portion SP2 may have a frame shape surrounding the substrate RP. The first portion SP1 may be disposed to be adjacent to the substrate RP (e.g., closest to the substrate RP), and the second portion SP2 may be disposed to be spaced apart from the substrate RP with the first portion SP1 therebetween. The first portion SP1 may be a portion which is in contact with the substrate RP. In an embodiment, the first portion SP1 and the second portion SP2 may have an integral shape such as to define a single body.

The first portion SP1 may be a portion of which a thickness of the support SSP increases in a direction from an inside of the support SSP (or the opening OP) toward the outside of the support SSP (or the outer surface S-OF). As the top surface of the first portion SP1 includes the inclined surface, the first portion SP1 may have a shape of which a thickness of the support SSP increases toward the outside of the support SSP. The second portion SP2 may be a portion of the support SSP having a constant thickness. Since the top surface of the second portion SP2 includes a flat surface, the second portion SP2 may have a constant thickness. In this specification, the first portion SP1 may be referred to as an inclined part.

A material of the support SSP is not particularly limited, but a material having high heat resistance may be used. Thus, even if heat is provided to the support SSP, deformation of the support SSP may be suppressed, and processability of the resin composition which is in contact with the support SSP may be improved. In an embodiment, the support SSP may include a heat-resistant polymer or a metal.

In an embodiment, the support SSP may include a heat-resistant polymer. The heat-resistant polymer may be a polymer having high heat stability. For example, the heat-resistant polymer may include polyimide, polyethersulfone, polyacrylonatrile, polyamide, polysulfone, polyetherketone, polyethylene terephthalate, polyester, polytetrafluoroethylene, polyurethane, cellulose acetate, polyester sulfone, polyetherimide, polycarbonate, and polyacrylate.

In an embodiment, the support SSP may include a heat conductive material such as a metal. For example, the support SSP may include at least one of stainless use steel (SUS), aluminum (Al), nickel (Ni), chromium (Cr), and molybdenum (Mo). However, the material of the support SSP is not limited thereto.

In an embodiment, the support SSP may include a hydrophobic material. As the support SSP includes the hydrophobic material, affinity between the resin composition RC (see FIG. 9C) and the support SSP may be reduced, and thus, movement along surfaces of the support SSP of the resin composition RC (see FIG. 9C) which is in contact with the support SSP may be facilitated. The hydrophobic material may include at least one of hydrophobic polymers such as a fluorinated resin, parylene, and Teflon. The support SSP may be formed by adding the hydrophobic material to a base material including the aforementioned heat-resistant polymer. Alternatively, the support SSP may be formed by surface-treating the support substrate made of the aforementioned heat-resistant polymer, with the aforementioned hydrophobic material. However, the embodiment is not limited thereto, and the support SSP may be made solely of the hydrophobic polymer if the hydrophobic polymer has sufficient heat resistance.

In an embodiment, the support SSP may include a metal, and at least a portion of the metal surface of the support SSP may be treated with the hydrophobic material. For example, the support SSP may include a metal, and at least the first sub-surface SF1 of a metal body of the support SSP may be treated with the hydrophobic material. However, the embodiment is not limited thereto, and all of the surfaces constituting a substrate body of the support SSP may be treated with the hydrophobic material. For example, all the bottom surface S-LF, the first sub-surface SF1, the second sub-surface SF2, the inner surface S-IF, and the outer surface S-OF of the support SSP may be surface-treated with the hydrophobic material. As the first sub-surface SF1 which is in contact with the resin composition RC (see FIG. 9C) is hydrophobic-treated, the affinity with the resin composition may be reduced, and thus, the movement of the resin composition RC (see FIG. 9C) which is in contact with the first sub-surface SF1 may be facilitated.

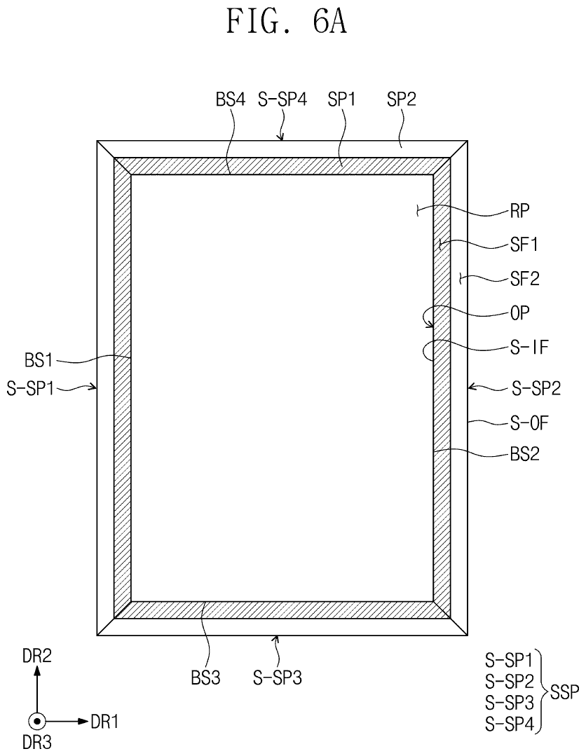

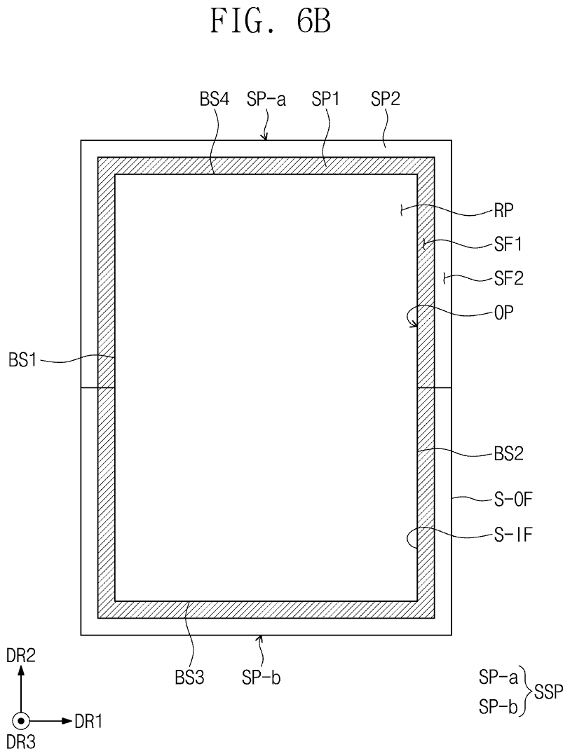

FIGS. 6A and 6B are plan views illustrating some of constituent elements of the apparatus for manufacturing the display device DD according to an embodiment of the invention. FIGS. 6A and 6B are plan views illustrating the support SSP provided in the apparatus for manufacturing the display device DD according to an embodiment of the invention. Hereinafter, in description of the apparatus for manufacturing the display device DD according to an embodiment with reference to FIGS. 6A and 6B, the same reference numerals will be given to the same components as those described above, and detailed descriptions will be omitted.

The support SSP illustrated in FIGS. 6A and 6B may be different from the support SSP illustrated in FIGS. 5A to 5C in that the support SSP illustrated in FIGS. 5A to 5C have an integrated shape, but the support SSP illustrated in FIGS. 6A and 6B are provided to be divided. FIG. 6A shows inclined dividing lines at corresponding corners of the first portion SP1 and the second portion SP2. The dividing lines correspond to a boundary between adjacent extended portion of the support SSP As illustrated in FIGS. 6A and 6B, when the support SSP is provided by being divided into a plurality of parts (e.g., extended portions), even if the support SSP is expanded by heat, and its shape is deformed, positions of the divided parts may be changed to be rearranged in a desired shape. Thus, even if the support SSP undergoes thermal expansion, the support SSP may be maintained to be in close contact with the substrate RP, the resin composition RC (see FIG. 9C) may be easily processed.

Referring to FIGS. 6A and 6B, the support SSP may include a plurality of sub-supports. The plurality of sub-supports may be connected to or meet each other to define the opening OP in which a substrate RP is disposed. The plurality of sub-supports may be provided which are detachably coupled to each other. Any separable coupling method may be utilized for coupling the plurality of sub-supports. For example, the plurality of sub-supports may be provided to be fixed by a separate fixing member which limits the movement of the plurality of sub-supports. Alternatively, the plurality of sub-supports may be fixed to each other by a mechanical fastening method such as screw fastening. An overall shape of the support SSP in which the plurality of sub-supports are connected to each other in FIGS. 6A and 6B may be the same as the overall shape of the support SSP illustrated in FIGS. 5A to 5C.

Referring to FIG. 6A, the support SSP may include a plurality of sub-supports S-SP1, S-SP2, S-SP3, and S-SP4, which correspond to a plurality of side surfaces BS1, BS2, BS3, and BS4 of the substrate RP, respectively. The support SSP may include first to fourth sub-supports S-SP1, S-SP2, S-SP3, and S-SP4. The first to fourth sub-supports S-SP1, S-SP2, S-SP3, and S-SP4 may be connected to each other to define the opening OP in which the substrate RP is disposed. The first sub-support S-SP1 and the second sub-support S-SP2 may face each other while being spaced apart from each other in the first direction DR1. The third sub-support S-SP3 and the fourth sub-support S-SP4 may face each other while being spaced apart from each other in the second direction DR2.

The first sub-support S-SP1 may be disposed adjacent to the first side surface BS1 of the substrate RP, the second sub-support S-SP2 may be disposed adjacent to the second side surface BS2 of the substrate RP, the third sub-support S-SP3 may be disposed adjacent to the third side surface BS3 of the substrate RP, and the fourth sub-support S-SP4 may be disposed adjacent to the fourth side BS4 of the substrate RP. The first sub-support S-SP1 may be in contact with the first side surface BS1 of the substrate RP, the second sub-support S-SP2 may be in contact with the second side surface BS2 of the substrate RP, the third sub-support S-SP3 may be in contact with the third side surface BS3 of the substrate RP, and the fourth sub-support S-SP4 may be in contact with the fourth side BS4 of the substrate RP. Each of the first to fourth sub-supports S-SP1, S-SP2, S-SP3, and S-SP4 may

include a first portion SP1 and a second portion SP2. The contents described in FIGS. 5A and 5B may be equally applied to the first portion SP1 and the second portion SP2 within a respective sub-support. That is, the first portion SP1 included in each of the first to fourth sub-supports S-SP1, S-SP2, S-SP3, and S-SP4 may be disposed adjacent to the substrate RP. The first portion SP1 may include a first sub-surface SF1 inclined at a predetermined angle with respect to the top surface of the substrate RP. The second portion SP2 may be disposed spaced apart from the substrate RP with the first portion SP1 therebetween. The second portion SP2 may include a second sub-surface SF2 parallel to the top surface of the substrate RP. In an embodiment, the first portion SP1 and the second portion SP2 respectively included in each of the first to fourth sub-supports S-SP1, S-SP2, S-SP3, and S-SP4 may have an integrated shape such that the respective sub-support may be a single body.

Referring to FIG. 6B, the support SSP may be provided divided into two parts. FIG. 6B shows dividing lines along sub-supports extended in the second direction DR2. The support SSP may be provided divided into two parts each having in a “C” shape. The support SSP may include a fifth sub-support SP-a and a sixth sub-support SP-b. The support SSP may be constituted by the fifth sub-support SP-a and the sixth sub-support SP-b assembled with each other. The fifth sub-support SP-a and the sixth sub-support SP-b may be connected to each other to define the opening OP in which the substrate RP is disposed. The fifth sub-support SP-a may be in contact with the entire fourth side BS4 of the substrate RP and may be in contact with a portion of each of the first and second side surfaces BS1 and BS2. The sixth sub-support SP-b may be in contact with the entire third side surface BS3 of the substrate RP and may be in contact with the remaining portion of each of the first and second side surfaces BS1 and BS2, which are not in contact with the fifth sub-support SP-a.

Each of the fifth and sixth sub-supports SP-a and SP-b may include a first portion SP1 and a second portion SP2. The contents described in FIGS. 5A and 5B may be equally applied to the first portion SP1 and the second portion SP2. That is, the first portion SP1 included in each of the fifth and sixth sub-supports SP-a and SP-b may be disposed adjacent to the substrate RP. The first portion SP1 may include a first sub-surface SF1 inclined at a predetermined angle with respect to the top surface of the substrate RP. The second portion

SP2 may be disposed spaced apart from the substrate RP with the first portion SP1 therebetween. The second portion SP2 may include a second sub-surface SF2 parallel to the top surface of the substrate RP. In an embodiment, the first portion SP1 and the second portion SP2 included in each of the fifth and sixth sub-supports SP-a and SP-b may have an integrated shape.

The divided shape of the support SSP is not limited to the embodiment illustrated in FIGS. 6A and 6B. The plurality of sub-supports constituting the support SSP may be provided in various shapes which surround at least a portion of the side surface BS1, BS2, BS3, and BS4 of the substrate RP (see FIG. 5A). For example, unlike as illustrated in FIGS. 6A and 6B, the support SSP may have a structure divided into four parts in an “L” shape.

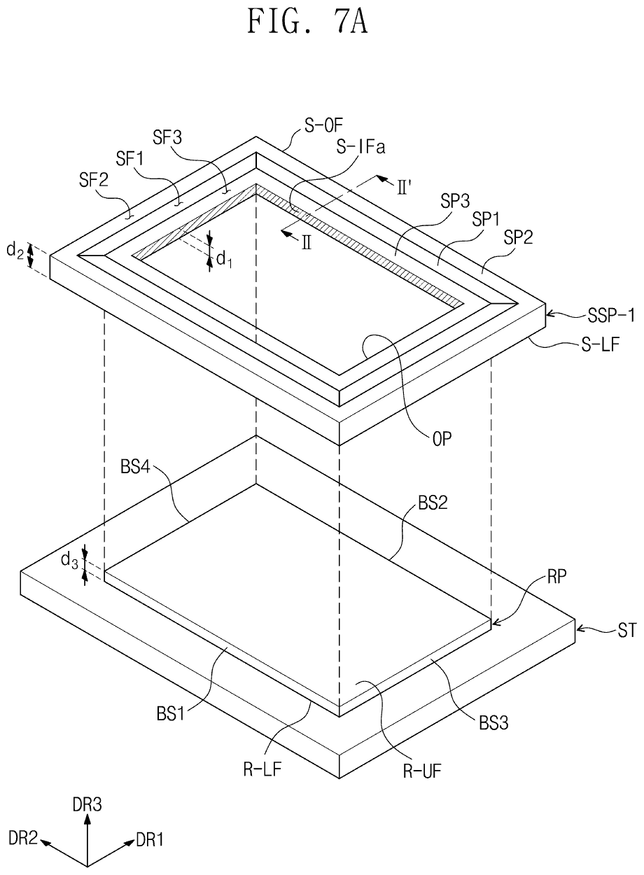

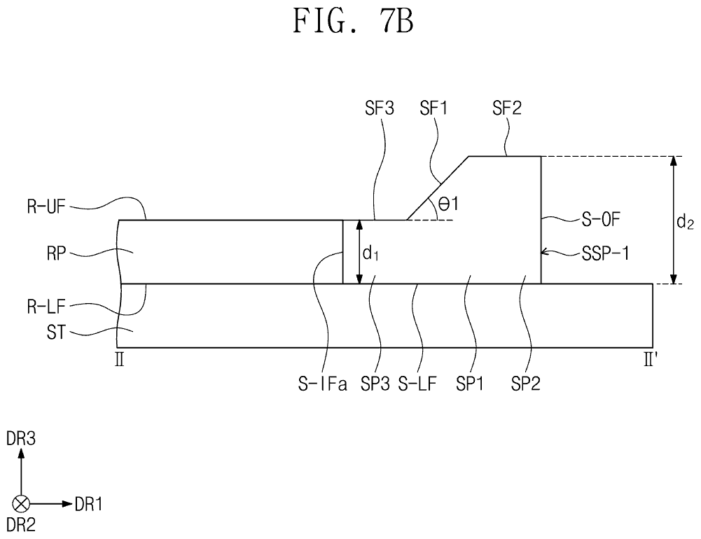

FIGS. 7A and 7B are schematic views illustrating the apparatus for manufacturing the display device DD according to an embodiment of the invention. FIG. 7A is a perspective view illustrating the apparatus for manufacturing the display device DD according to an embodiment of the invention. FIG. 7B is a cross-sectional view taken along line II-II′ of FIG. 7A. In FIGS. 7A and 7B, the substrate RP, which is an object to be processed, is illustrated together with the apparatus for manufacturing the display device. Hereinafter, in description of the apparatus for manufacturing the display device according to an embodiment with reference to FIGS. 7A and 7B, the same reference numerals will be given to the same components as those described above, and detailed descriptions will be omitted.

The apparatus for manufacturing the display device illustrated in FIGS. 7A and 7B is different from the apparatus for manufacturing the display device illustrated in FIGS. 5A and 5B in the shape of the support. The support SSP-1 illustrated in FIGS. 7A and 7B may further include a third sub-surface SF3 compared to the support SSP illustrated in FIGS. 5A to 5C. That is, the apparatus for manufacturing the display device illustrated in FIGS. 7A and 7B may further include a third portion SP3 as a third thickness portion including the third sub-surface SF3 compared to the apparatus for manufacturing the display device illustrated in FIGS. 5A to 5C.

Referring to FIGS. 7A and 7B, the apparatus for manufacturing the display device DD according to an embodiment of the invention may include a stage ST, a support SSP-1, and a heater (not shown). The contents described above in FIGS. 5A to 5C may be equally applied to the stage ST and the heater (not shown).

The support SSP-1 may include top surfaces SF1, SF2, and SF3, a bottom surface S-LF, an inner surface S-IFa, and an outer surface S-OF. The bottom surface S-LF may be parallel to the plane defined by the first direction DR1 and the second direction DR2.

The top surface SF1, SF2, and SF3 may include a first sub-surface SF1, a second sub-surface SF2, and a third sub-surface SF3. The top surfaces SF1, SF2, and SF3 of the support SSP-1 may be defined by the first sub-surface SF1, the second sub-surface SF2, and the third sub-surface SF3, respectively.

Each of the inner surface S-IFa and the outer surface S-OF may be a side surface extending from the bottom surface S-LF. Each of the inner surface S-IFa and the outer surface S-OF may be a surface parallel to the third direction DR3 intersecting the first direction DR1 and the second direction DR2. The inner surface S-IFa may connect the bottom surface S-LF to the third sub-surface SF3, and the outer surface S-OF may connect the bottom surface S-LF to the second sub-surface SF2. The inner surface S-IFa and the outer surface S-OF may face each other in the first direction DR1 or the second direction DR2.

In an embodiment, a height of the inner surface S-Ifa as an innermost surface of the support SSP-1 may be less than that of the outer surface S-OF as an outermost surface of the support SSP-1. The height of the inner surface S-IFa may be defined as a first length dl. The first length d1 may be a length from the bottom surface S-LF to the uppermost end of the inner surface S-IFa. One end of the inner surface S-IFa may be in contact with the bottom surface S-LF, and the other end of the inner surface S-IFa may be in contact with the third sub-surface SF3. The other end of the inner surface S-IFa may be the uppermost end of the inner surface S-IFa. A height of the outer surface S-OF may be defined as a second length d2. The second length d2 may be a length from the bottom surface S-LF to the uppermost end of the outer surface S-OF. One end of the outer surface S-OF may be in contact with the bottom surface S-LF, and the other end of the outer surface S-OF may be in contact with the second sub-surface SF2. The other end of the outer surface S-OF may be the uppermost end of the outer surface S-OF.

The inner surface S-IFa of the support SSP-1 may define the opening OP in which the substrate RP is disposed. The inner surface S-IFa of the support SSP-1 may be disposed adjacent to the substrate RP. The inner surface S-IFa may be in contact with the substrate RP.

The first sub-surface SF1 may be an inclined surface which is inclined at a predetermined angle θ1. The first sub-surface SF1 may be inclined at a predetermined angle with respect to the top surface R-UF of the substrate RP. One end of the first sub-surface SF1 may be in contact with the inner surface S-IFa, and the other end of the first sub-surface SF1 may be in contact with the second sub-surface SF2. An angle at which the first sub-surface SF1 is inclined may be defined as a first angle θ1. That is, the first sub-surface SF1 may be inclined at a first angle θ1 with respect to the top surface R-UF of the substrate RP. In an embodiment, the first angle θ1 may be greater than or equal to about 20 degrees and less than or equal to about 85 degrees.

The second sub-surface SF2 may extend from the first sub-surface SF1 toward the outside of the support SSP-1. The second sub-surface SF2 may be parallel to the plane defined by the first direction DR1 and the second direction DR2. The second sub-surface SF2 may be parallel to the top surface R-UF of the substrate RP. One end of the second sub-surface SF2 may be in contact with the first sub-surface SF1, and the other end of the second sub-surface SF2 may be in contact with the outer surface S-OF.

The third sub-surface SF3 may extend from the first sub-surface SF1 toward the inside of the support SSP-1. The third sub-surface SF3 may be parallel to the plane defined by the first direction DR1 and the second direction DR2. The third sub-surface SF3 may be parallel to the top surface R-UF of the substrate RP. One end of the third sub-surface SF3 may be in contact with the first sub-surface SF1, and the other end of the second sub-surface SF2 may be in contact with the inner surface S-IFa. In an embodiment, the first to third sub-surfaces SF1, SF2, and SF3 may define a top surface of the support SSP-1.

In the state in which the substrate RP is disposed within the opening OP, the top surface R-UF of the substrate RP may be disposed on the same line as at least a portion of the third sub-surface SF3. That is, the top surface R-UF of the substrate RP may be coplanar with a portion of the third sub-surface SF3. When the substrate RP is disposed within the opening OP of the support SSP-1, the side surfaces BS1, BS2, BS3, and BS4 of the substrate RP may be aligned with and facing the inner surface S-IFa of the support SSP-1, and the top surface R-UF of the substrate RP and the third sub-surface SF3 of the support SSP-1 may define one continuous surface. Specifically, when the side surfaces BS1, BS2, BS3, and BS4 of the substrate RP are in contact with the inner surface S-IFa of the support SSP-1, a single plane extending from the top surface R-UF of the substrate RP to the third sub-surface SF3 may be defined.

In the state in which the substrate RP is disposed within the opening OP, the top surface R-UF of the substrate RP and the first and third sub-surfaces SF1 and SF3 of the support SSP-1 may define the accommodation space (or volume) in which the resin composition RC (see FIG. 9C) described below is provided. In the state in which the substrate RP is disposed within the opening OP, the resin composition RC (see FIG. 9C) may be provided in the accommodation space defined by the top surface R-UF, the first sub-surface SF1, and the third sub-surface SF3 of the substrate RP and then be processed. This will be explained in detail later.

In the apparatus for manufacturing the display device DD according to an embodiment, the support SSP-1 may include a first portion SP1, a second portion SP2, and a third portion SP3. On the plane, each of the first to third portions SP1, SP2, and SP3 may have a frame shape surrounding the substrate RP. As illustrated in FIGS. 7A and 7B, the third portion SP3, the first portion SP1, and the second portion SP2 may be sequentially disposed with respect to one direction toward the outside of the support SSP-1. The third portion SP3 may be disposed to be closest to the substrate RP among the first to third portions SP1, SP2, and SP3. The third portion SP3 may be a portion which is in contact with the substrate RP.

The inner surface S-IFa of the support SSP-1 may be defined by an inner side surface of the third portion SP3. The first portion SP1 may be disposed between the second portion SP2 and the third portion SP3. The second portion SP2 may be disposed at the outermost side of the support SSP-1. The second portion SP2 may be spaced from the third portion SP3 with the first portion SP1 therebetween. In an embodiment, the first portion SP1, the second portion SP2, and the third portion SP3 may have an integrated shape.

With respect to the plane defined by the first direction DR1 and the second direction DR2, the inclination of the top surface of the first portion SP1 may be different from the inclination of the top surfaces of each of the second and third portions SP2 and SP3. The top surface of the first portion SP1 may include an inclined surface which is inclined at a predetermined angle. The top surface of each of the second and third portions SP2 and SP3 may be parallel to the plane defined by the first direction DR1 and the second direction DR2. The top surface of the first portion SP1 may correspond to the first sub-surface SF1 described above, the top surface of the second portion SP2 may correspond to the second sub-surface SF2 described above, and the top surface of the third portion SP3 may correspond to the third sub-surface SF3 described above.

The first portion SP1 may be a portion of which a thickness of the support SSP-1 increases in a direction toward the outside of the support SSP-1. As the top surface of the first portion SP1 includes the inclined surface, the first portion SP1 may have a shape of which a thickness of the support SSP-1 increases in the direction toward the outside of the support SSP-1. Each of the second and third portions SP2 and SP3 may be a thickness portion of the support SSP-1 having a constant thickness. Since each of the top surfaces of the second and third portions SP2 and SP3 includes a flat surface, each of the second and third portions SP2 and SP3 of the support SSP-1 may have a constant thickness.

In an embodiment, the thickness of the support SSP-1 at the second portion SP2 may be greater than the thickness of the support SSP-1 at the third portion SP3. The second portion SP2 the support SSP-1 may have a constant second thickness, and the third portion SP3 may have a first thickness which is less than the second thickness. The first thickness may be defined as the first length d1 described above, and the second thickness may be defined as the second length d2 described above. In this specification, the first portion SP1 may be referred to as an inclined part, and the third portion SP3 may be referred to as a flat part.

The material of the support SSP-1 may be applied in the same manner as described above through FIGS. 5A to 5C. However, if the support SSP-1 is provided by the surface treatment of the hydrophobic material on a support body, at least the first sub-surface SF1 and the third sub-surface SF3 of the support SSP-1 may be treated with the hydrophobic material. Since the first sub-surface SF1 and the third sub-surface SF3 which are in contact with the resin composition are hydrophobic-treated, their affinity with the resin composition may be reduced, and thus, the resin composition which is in contact with the first sub-surface SF1 and the third sub-surface SF3 may easily move.

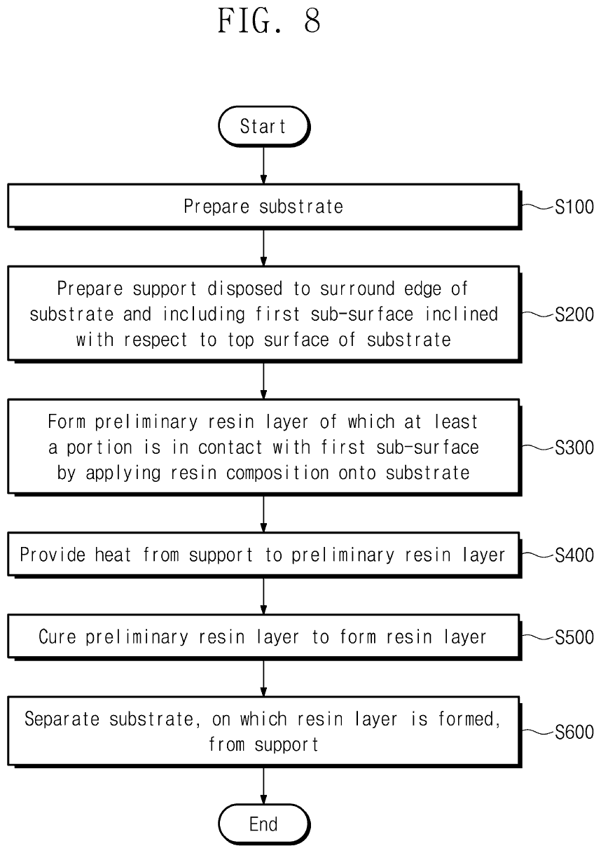

Hereinafter, a method for manufacturing a display device DD according to an embodiment will be described with reference to FIGS. 8 and 9A to 9G. In description of the method for manufacturing the display device DD according to an embodiment of the invention, the display device DD may be applied to the display device DD, DD-1 and/or DD-2 according to the abovementioned embodiment of the invention. Hereinafter, in description of the method for manufacturing the display device DD according to an embodiment of the invention, duplicated description will be omitted, and thus, differences therebetween will be mainly described.

The method for manufacturing the display device DD according to an embodiment of the invention may be a method for manufacturing the display devices DD, DD-1, and DD-2 of FIGS. 1 to 4B according to an embodiment of the invention. In an embodiment, a method for manufacturing a display device DD including a resin layer AP disposed on a display panel DP of each of the display device DD, DD-1, and DD-2 may be provided.

FIG. 8 is a flowchart illustrating a method for manufacturing a display device DD according to an embodiment of the invention.

Referring to FIG. 8, a method for manufacturing a display device of an embodiment includes preparing a substrate (S100), preparing a support including a first sub-surface which is disposed to surround an edge of the substrate and inclined with respect to a top surface of the substrate (S200), applying a resin composition onto the substrate to form a preliminary resin layer of which at least a portion is in contact with the first sub-surface (S300), providing heat from the support to the preliminary resin layer (S400), curing the preliminary resin layer to form a resin layer (S500), and separating the substrate, on which the resin layer is formed, from the support (S600).

FIGS. 9A to 9G are schematic views illustrating forming (or providing) the resin layer AP on a substrate RP according to an embodiment of the invention. FIGS. 8A to 8H illustrate processes for manufacturing the display panel DP in the cross-section corresponding to FIG. 5C, respectively. That is, the method illustrated in FIGS. 8A to 8H may be applied to any of a number of base structures such as the window WP, the display module DM, the light control layer PP, the display panel DP, etc., without being limited thereto. That is, the substrate RP illustrated within the various embodiments of the apparatus and the method of providing the display device DD may represent a base structure including various layers of the display device DD.

FIG. 9A illustrates preparing of the substrate RP, FIG. 9B illustrates preparing of the support SSP, FIGS. 9C and 9D illustrate forming of the preliminary resin layer P-RL by applying the resin composition RC onto the substrate RP, FIG. 9E illustrates providing of the heat from the support SSP to the preliminary resin layer P-RL, FIG. 9F illustrates forming of the resin layer AP by curing the preliminary resin layer P-RL, and FIG. 9G illustrates separating of the substrate RP on which the resin layer AP has been formed from the support SSP.

Referring to FIG. 9A, the method for manufacturing the display device DD according to an embodiment may include providing the substrate RP on which the resin layer AP (see FIG. 9G) is to be formed. The providing the substrate RP may include seating the substrate RP on the stage ST. The substrate RP may provide a reference surface on which the resin layer AP (see FIG. 9G) is formed. For example, the substrate RP may be a window WP or a display module DM as described in FIGS. 2 to 4B. However, the embodiment is not limited thereto, and the substrate RP may be the display panel DP described in FIGS. 3 to 4B.

Referring to FIG. 9A, the substrate RP may include a top surface R-UF, a bottom surface R-LF, and a side surface R-F connecting the top surface R-UF to the bottom surface R-LF. The side surface R-F illustrated in FIG. 9A may correspond to at least one of the plurality of side surfaces BS1, BS2, BS3, and BS4 described in FIG. 5A, etc. For example, the side surface R-F illustrated in FIG. 9A may correspond to the second side surface BS2. The side surface of the substrate RP may be in contact with the support SSP described later. As being in contact, elements may form an interface therebetween.

Referring to FIG. 9B, the method for manufacturing the display device DD according to an embodiment may include preparing the support SSP. The support SSP may be disposed to surround an outer edge of the substrate RP. The inner side surface of the support SSP may be disposed to be in contact with the side surface R-F of the substrate RP. The support SSP may include a first portion SP1 and a second portion SP2. The contents described in FIGS. 5A to 5C may be equally applied to the first portion SP1 and the second portion SP2. The first portion SP1 may include a first portion SP1 including a first sub-surface SF1 which is inclined at a predetermined angle with respect to the top surface R-UF of the substrate RP. The second portion SP2 may include a second sub-surface SF2 parallel to the top surface R-UF of the substrate RP. The first portion SP1 may be a portion which is in contact with the side surface R-F of the substrate RP. The stage ST including the support SSP and the substrate RP which is assembled with the support SSP may together define a preliminary stacked structure.

Referring to FIGS. 9C and 9D, the method for manufacturing the display device DD according to an embodiment may include forming the preliminary resin layer by applying the resin composition on the substrate RP which is on the stage ST and surrounded by the support SSP. The preliminary resin layer P-RL may be formed by applying a resin material like the resin composition RC on the substrate RP. The resin composition RC may be provided in a liquid state, and the preliminary resin layer P-RL may be a liquid layer before curing.

The resin composition RC may include an optical clear resin or an optical clear adhesive. The optically transparent resin and the optically transparent adhesive are not particularly limited, but may be, for example, polyurethane-based, polyacrylic-based, polyester-based, polyepoxy-based, polyvinyl acetate-based, etc., and a mixture of one or two or more of these may be used, but is not limited thereto.

The resin compositions RC may be provided in various manners. For example, the resin composition RC may be provided by a method such as spin-coating, slot-die, ink-jet printing, spray coating, etc. As illustrated in FIG. 9C, the resin composition RC may be provided through a supply nozzle NZ. The resin composition RC may be provided in an accommodation space which is defined by the top surface R-UF of the substrate RP together with the first sub-surface SF1 of the support SSP and open in the third direction DR3. The resin composition RC may be provided to entirely cover the top surface R-UF of the substrate RP. In addition, at least a portion of the resin composition RC may be provided on the first portion SP1 of the support SSP. That is, the resin composition RC may be provided on the top surface R-UF of the substrate RP and extend from the top surface R-UF and onto the first sub-surface SF1 of the support SSP.

The resin composition RC as an uncured resin material may include an uncured oligomer or a monomer. The uncured oligomer or monomer may contain a crosslinking group. In addition, the resin composition RC may include an initiator. The type of initiator is not particularly limited as long as it may promote the curing reaction, and may be, for example, a photoinitiator.

The resin composition RC may include at least one photoinitiator. In an embodiment, the photoinitiator may be a photoinitiator which is activated by light in the ultraviolet range. The photoinitiator may be a photoinitiator which is activated by ultraviolet light having a center wavelength in the wavelength range of 100 nm to 400 nm. When the resin composition RC contains a plurality of photoinitiators, different photoinitiators may be activated by ultraviolet light having different center wavelength ranges. In this specification, the central wavelength represents a wavelength representing a maximum intensity of an emission peak in an emission spectrum of a light source.

For example, the photoinitiator may be one selected from 2,2-dimethoxy-1,2-diphenylethan-1-one, 1-hydroxy-cyclohexyl-phenyl-ketone, 2-hydroxy-2-methyl-1-phenyl-1-propanone, 2-hydroxy-1-[4-(2-hydroxyethoxy)phenyl]-2-methyl-1-propanone, and 2-hydroxy-1-{4-[4-(2-hydroxy-2-methyl-propionyl)-benzyl]-phenyl}-2- methylpropan-1-one. In addition, the photoinitiator may be one selected from 2-methyl-1 [4-(methylthio)phenyl]-2-morpholinopropan-1-one, 2-benzyl-2-dimethylamino-1-(4-morpholinophenyl)-butanone-1,2-dimethylamino-2-(4-methyl-benzyl)-1-(4-morpholin-4-yl-phenyl)-butan-1-one, 2,4,6-trimethylbenzoyl-diphenylphosphine oxide, 2,4,6-trimethylbenzoyl-diphenyl phosphinate, bis(2,4,6-trimethylbenzoyl)-phenylphosphincoxide, [1-(4-phenylsulfanylbenzoyl) heptylidencamino]benzoate, [1-[9-ethyl-6-(2-methylbenzoyl)carbazol-3-yl]ethylidencamino] acetate, and Bis(2,4-cyclopentadienyl) bis[2,6-difluoro-3-(1-pyrryl)phenyl] titanium (IV). However, the embodiment of the invention is not limited thereto.

The resin composition RC may further contain an additive as necessary. The additive may be appropriately selected from general additives known in the art to control properties required for the adhesive composition. For example, the additive may include, but are not limited to, light stabilizers, cross-linking agents, antioxidants, chain transfer agents, photosensitizers, polymerization inhibitors, leveling agents, surfactants, adhesion-imparting agents, plasticizers, ultraviolet absorbers, storage stabilizers, antistatic agents, inorganic fillers, pigments, and dyes. The additive may be used alone or in combination of two or more types.

Referring to FIG. 9D, the preliminary resin layer P-RL formed from a resin composition RC may be entirely disposed on the top surface R-UF of a substrate RP. The preliminary resin layer P-RL may cover an entirety of the top surface R-UF of the substrate RP. In addition, at least a portion of the preliminary resin layer P-RL may be disposed along the first sub-surface SF1 of the support SSP. At least a portion of the preliminary resin layer P-RL may be in contact with the first sub-surface SF1 of the support SSP. A portion of the preliminary resin layer P-RL disposed on the top surface R-UF of the substrate RP may be referred to as a first resin portion, and a portion of the preliminary resin layer P-RL disposed on the first sub-surface SF1 of the support SSP may be referred to as a second resin portion.

Referring to FIG. 9D, prior to providing the heat to the preliminary resin layer P-RL, the preliminary resin layer P-RL may have a cross-sectional shape in which the top surface PR-UF is wider than the lower surface PR-LF. As a portion of the preliminary resin layer P-RL extends further than outer side surfaces of the substrate RP to be in contact with the first sub-surface SF1 of the support SSP, a total planar area of the top surface PR-UF of the preliminary resin layer P-RL may be greater than a total planar area of the lower surface PR-LF of the preliminary resin layer P-RL. For example, as illustrated in FIG. 9D, the preliminary resin layer P-RL may have an inverse trapezoidal shape in cross-section in which the top surface PR-UF is wider than the lower surface PR-LF. While the view in FIGS. 9C and 9D are of a DR1-DR3 plane, the various descriptions herein may also be applied to a DR2-DR3 plane, without being limited thereto.

Referring to FIG. 9E, the method of manufacturing the display device DD according to an embodiment may include providing heat HT from the support SSP to the preliminary resin layer P-RL. The support SSP may be heated by operating the heater (not shown). For example, the heater (not shown) may be installed inside the support SSP and may operate to heat the support SSP after the preliminary resin layer P-RL is applied on the substrate RP. Here, the heater (not shown) may be provided with a driving part to selectively generate heat only after the preliminary resin layer P-RL is applied on the substrate RP.

In the method for manufacturing the display device according to an embodiment illustrated in FIGS. 9A to 9G, the heater (not shown) may be installed inside the support SSP, and the support SSP may be selectively heated, but the embodiment is not limited thereto. The heater (not shown) may be installed in a separate device (not shown) which accommodates and drives a heating device of the heater (not shown) to transfer heat to the support SSP. In this case, the support SSP may be provided by being pre-heated in advance in the preparing the support SSP, and the forming the preliminary resin layer P-RL and the providing the heat to the preliminary resin layer P-RL may be performed at the same time (e.g., simultaneously).

Referring again to FIG. 9E, when the support SSP is heated (shown by shading of the support SSP), the heat HT may be transferred from the support SSP to the preliminary resin layer P-RL. A surface tension of a fluid may vary depending on a temperature. Thus, when a temperature difference is applied to the fluid, the surface tension may decrease at a high-temperature portion and increase at a low-temperature portion, and a surface tension gradient may cause the fluid to move in a direction from the high-temperature portion to the low-temperature portion. This fluid movement is called Marangoni convection. In the providing the heat HT from the support SSP to the preliminary resin layer P-RL, the second resin portion which is in contact with the support SSP in the preliminary resin layer P-RL may be heated. A portion of the preliminary resin layer P-RL which is in contact with the first sub-surface SF1 of the support SSP may be heated to a higher temperature as compared to a temperature of a portion which is not in contact with the first sub-surface SF1 of the support SSP and adjacent to the first sub-surface SF1. Since the surface tension of the portion which is in contact with the first sub-surface SF1 in the preliminary resin layer P-RL is reduced, at least a portion of the portion which is in contact with the first sub-surface SF1 may move from the first sub-surface SF1 toward the center of the substrate RP (e.g., in a direction away from the support SSP).

The second resin portion disposed on the first sub-surface SF1 of the preliminary resin layer P-RL may be heated to a higher temperature than the first resin portion which is disposed on the top surface R-UF of the substrate RP. Thus, since the surface tension of the second resin portion is reduced, at least a portion of the second resin portion may move from the first sub-surface SF1 toward a central portion of the substrate RP. The temperature difference between the first resin portion and the second resin portion, which are formed in providing the heat HT from the support SSP to the preliminary resin layer P-RL is not particularly limited as long as it may cause a flow of a material of the preliminary resin layer P-RL, but may be, for example, about 10 degrees Celsius (° C.) or more.

Referring to FIGS. 9D and 9E together, when a planar area at which the preliminary resin layer P-RL is in contact with the first sub-surface SF1 before the providing the heat HT to the preliminary resin layer P-RL is defined as a first contacting area, and a planar area at which the preliminary resin layer P-RL is in contact the first sub-surface SF1 after the providing the heat HT to the preliminary resin layer P-RL is defined as a second contact area, the second contact area may be less than the first contact area. In the providing the heat HT to the preliminary resin layer P-RL via the support SSP, as at least a portion of the preliminary resin layer P-RL which is in contact with the first sub-surface SF1 moves away from the support SSP and toward the central portion of the substrate RP, the contact area of the preliminary resin layer P-RL with respect to the first sub-surface SF1 may be reduced.

The support SSP may not be disposed on a lower portion of the substrate RP. The support SSP may not overlap the substrate RP in the plan view. Since the support SSP is disposed only on the side surface R-F of the substrate RP and not disposed on the lower portion, the heat HT provided from the support SSP may be maximally provided only to an edge portion of the preliminary resin layer P-RL. Thus, a temperature difference may occur between the edge portion and the central portion of the preliminary resin layer P-RL, and a Marangoni flow phenomenon from the edge portion to the central portion may effectively occur.

Referring to FIG. 9F, the method for manufacturing the display device DD according to an embodiment may include curing the preliminary resin layer P-RL to form the resin layer AP as a cured resin material. After providing the heat HT to the preliminary resin layer P-RL from the support SSP, the curing the preliminary resin layer P-RL may be performed. At least a portion of the preliminary resin layer P-RL which is in contact with the first sub-surface SF1 may be heated by the heat HT to move away from the support SSP and toward the central portion of the substrate RP, and thus, the preliminary resin layer P-RL may be cured to form the resin layer AP. That is, at least a portion of the preliminary resin layer P-RL which is in contact with the first sub-surface SF1 may move toward the central portion of the substrate RP through the Marangoni flow phenomenon, and then, the cross-sectional shape of the preliminary resin layer P-RL having the heated resin material may be fixed by photo-curing the moved resin material of the preliminary resin layer P-RL. That is, a final cross-sectional shape of the resin layer AP may be defined by heating of the uncured resin material, moving heated uncured resin material and curing the moved heated uncured resin material. Light LT may be applied to the entire preliminary resin layer P-RL as the moved heated resin material, and the preliminary resin layer P-RL including the photoinitiator may be cured by the light LT. For example, the preliminary resin layer P-RL may be cured by ultraviolet (UV) light.

Referring to FIGS. 9D to 9F together, after the providing the heat HT to the preliminary resin layer P-RL, the first planar area of the top surface PR-UF of the preliminary resin layer P-RL which is heated may be less than the second planar area of the top surface PR-UF of the preliminary resin layer P-RL which is unheated (e.g., before the providing the heat HT to the preliminary resin layer P-RL). That is, in the providing the heat HT to the preliminary resin layer P-RL, the planar area of the top surface PR-UF of the preliminary resin layer P-RL may gradually decrease over a time as the heat HT is applied. In the providing the heat HT to the preliminary resin layer P-RL, the planar area difference between the top surface PR-UF and the lower surface PR-LF of the preliminary resin layer P-RL may be reduced. In this specification, the top surface PR-UF of the preliminary resin layer P-RL may mean a surface parallel to the reference plane defined by the first direction DR1 and the second direction DR2, and the planar area of the top surface PR-UF of the preliminary resin layer P-RL may be a value calculated by calculating the planar area of a surface parallel to the reference plane at the surface of the preliminary resin layer P-RL exposed to the outside. Here, the exposed surface of the preliminary resin layer P-RL may correspond to a surface at which the resin layer AP is coupled to another layer.

The preliminary resin layer P-RL may be cured to form the resin layer AP as illustrated in FIG. 9G. The side surface R-OF of the substrate RP may be aligned with the side surface R-SF of the resin layer AP. In this specification, the “a side surface of a configuration A is aligned with a side surface of a configuration B” may mean that an edge of the configuration A and an edge of the configuration B are aligned with each other to define one parallel surface in a cross-section. That is, the side surface R-OF of the substrate RP may be coplanar with the side surface R-SF of the resin layer AP.

Referring to FIG. 9G, the method for manufacturing the display device DD according to an embodiment of the invention may include separating the support SSP from the substrate RP having the resin layer AP thereon. After the preliminary resin layer P-RL is cured, and the resin layer AP is formed, the support SSP may be separated from the substrate RP having the resin layer AP formed thereon. Thereafter, the resin layer AP manufactured in the processes of FIGS. 9A to 9G may be applied to the above-described display devices DD, DD-1, and DD-2. For example, the resin layer AP manufactured in the processes of FIGS. 9A to 9G may be attached to the display module DM described above at one side of the resin layer AP, such that the substrate RP in FIGS. 9A to 9G may represent the window WP coupled to the display module DM by the resin layer AP.

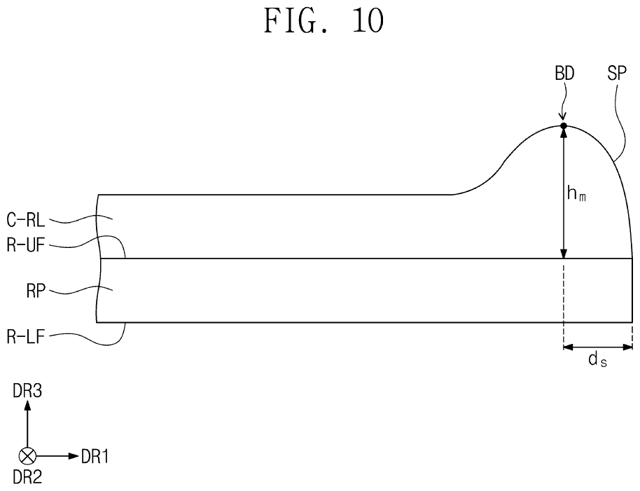

FIG. 10 is a cross-sectional view for explaining limitations which may occur in a method of providing the display device DD. The same configuration as that described in FIGS. 9A to 9G may be denoted by the same reference numerals, and their descriptions will be omitted.

A solution process such as spin-coating, slot-die, ink-jet printing, or spray coating may be used to form the resin layer AP which respectively attaches a layer included in the display device DD or a cover window included in the display device DD, to another layer.

Referring to FIG. 10, in the case of the solution process, a bead BD may be formed within the resin layer C-RL at the outer edge of the substrate RP due to the surface tension of the discharged liquid material for forming the resin layer C-RL. The bead BD may mean a portion of the resin layer C-RL having the maximum thickness in the third direction DR3 among thicknesses of the resin layer C-RL. That is, the bead BD may be formed at the edge of the resin layer C-RL and may mean a portion having a maximum height (hm) from a bottom surface of the resin layer C-RL closest to the substrate RP to a top surface of the resin layer C-RL which is spaced apart from and furthest from the substrate RP. The bead BD may cause a decrease in thickness uniformity of the resin layer C-RL and defects in layers which are coupled to each other by the resin layer C-RL. A method of removing the bead BD by flattening an upper surface of the bead BD or cutting and removing a portion of the substrate RP which correspond to the bead BD may be used. However, this method may have limitations in terms of process efficiency because of additionally involving the bead removal process as described above, which increases manufacturing cost and manufacturing time and increases in defect occurrence rate of the substrate RP. In addition, since an upper part of the resin layer C-RL has transverse shrinkage greater than that of a lower portion of the resin layer C-RL during the curing, the top surface of the resin layer C-RL may be slightly shrunk to generate a slope SP in which the thickness of the resin layer C-RL gradually decreases in a direction from the bead BD to the edge. If a length ds of this slope SP becomes longer, the slope SP may be recognized outside the display device DD to deteriorate image quality. The length ds of the slope SP may mean a horizontal distance between a point at which the bead BD and the resin layer C-RL meet the top surface R-UF of the substrate RP.

According to one or more embodiment of the invention, the support SSP surrounding the substrate RP may be disposed, and then, the surface tension of the resin composition RC at the edge of the substrate may be locally reduced by utilizing the thermal Marangoni flow phenomenon to improve the thickness uniformity of the resin layer AP at an outer edge thereof. Thus, the bead formation occurring at the edge portion of the resin layer C-RL may be suppressed, and thus, the above-described bead removal process may be omitted. As a result, the process according to one or more embodiment of the invention may be simplified to reduce the process cost. In addition, since the first sub-surface SF1 of the support SSP which is in contact with the resin composition is inclined at a predetermined angle, the liquid resin composition may have a shape of which the top surface is initially wider than the bottom surface, and thus, the large transverse shrinkage of the upper portion of the resin layer during the curing may be compensated to reduce the length of the slope. That is, an extended portion of the uncured resin material which protrudes further than an outer side surface of the substrate RP compensates for planar shrinkage of the uncured resin material layer at the extended portion, to reduce or effectively prevent a large thickness edge portion of the cured resin material layer.

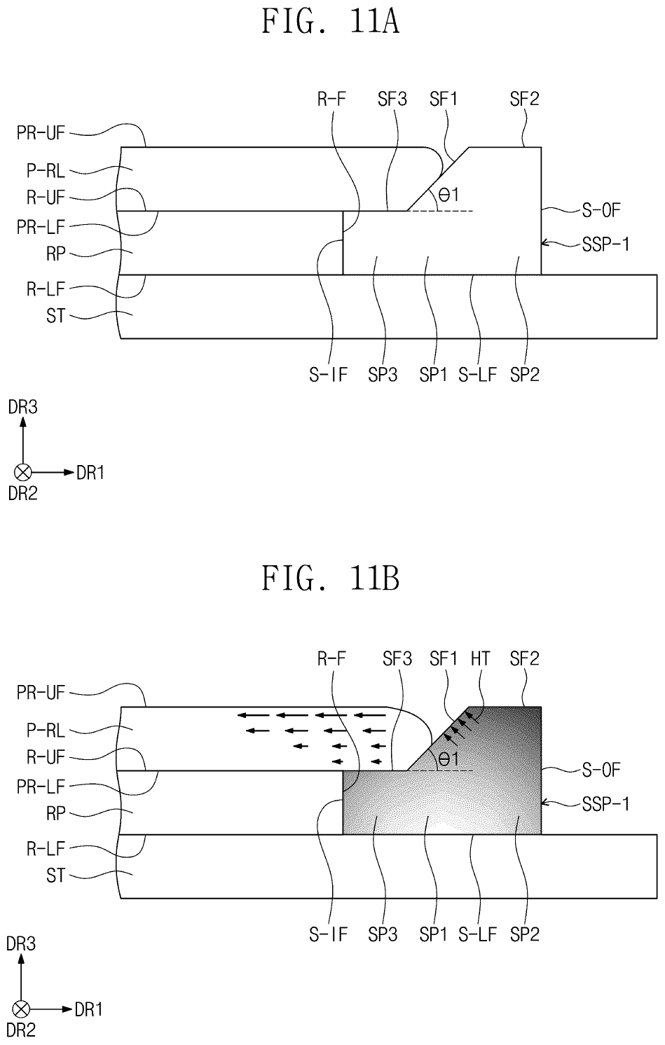

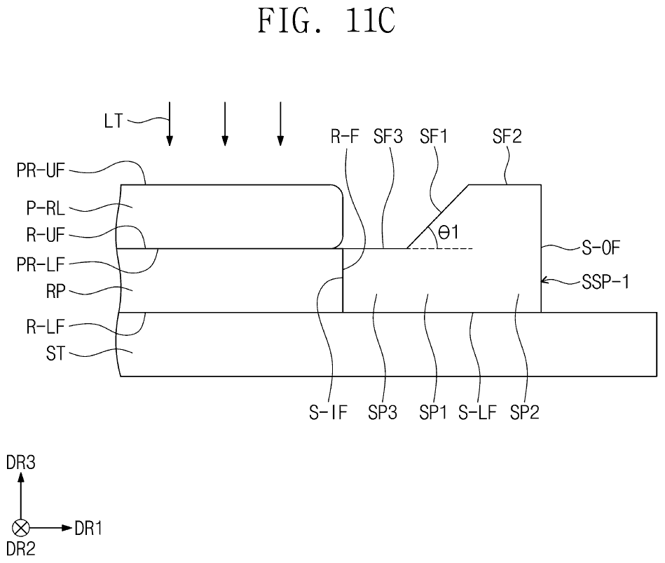

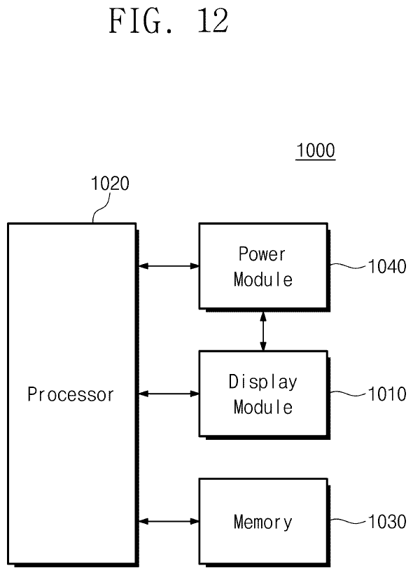

FIGS. 11A to 11C are cross-sectional views illustrating the method for manufacturing the display device DD according to an embodiment of the invention. FIGS. 11A to 11C illustrate processes for manufacturing the display device DD in a cross-section corresponding to FIG. 7B, respectively. Hereinafter, in description of the method for manufacturing the display device DD according to an embodiment with reference to FIGS.

11A and 11C, the same reference numerals will be given to the same components as those described above, and detailed descriptions will be omitted. The method for manufacturing the display device DD according to an embodiment of the invention may be a method for manufacturing the display devices DD, DD-1, and DD-1 of FIGS. 1 to 4B according to an embodiment of the invention. In an embodiment, a method for manufacturing a display device DD including a resin layer AP disposed on a display panel DP of each of the display device DD, DD-1, and DD-2 may be provided.

A support SSP-1 used in the method for manufacturing the display device DD illustrated in FIGS. 11A to 11C may have a different shape compared to the support SSP used in the method for manufacturing the display device DD illustrated in FIGS. 9A to 9G. The support SSP-1 used in the method for manufacturing the display device DD illustrated in FIGS. 11A to 11C may correspond to the support SSP-1 illustrated in FIGS. 7A and 7B.

Referring to FIG. 11A, the support SSP-1 may be disposed to surround the edge of the substrate RP. The support SSP-1 may be disposed to be in contact with the side surface R-F of the substrate RP. The support SSP-1 may include a first portion SP1, a second portion SP2, and a third portion SP3. The contents described in FIGS. 7A and 7B may be equally applied to the first to third portions SP1, SP2, and SP3. The first portion SP1 may include a first sub-surface SF1 inclined at a predetermined angle with respect to the top surface R-UF of the substrate RP. The second portion SP2 may include a second sub-surface SF2 parallel to the top surface R-UF of the substrate RP. The third portion SP3 may include a third sub-surface SF3 parallel to the top surface R-UF of the substrate RP. A thickness of the second portion SP2 may be greater than that of the third portion SP3. The third portion SP3 may be a portion which is in contact with the side surface R-F of the substrate RP.

After the support SSP is disposed to be in contact with the substrate RP, the resin composition RC (see FIG. 9C) may be applied on the substrate RP to form the preliminary resin layer P-RL to have an extended portion which protrudes further from the outer edge of the substrate RP. In the state in which the support SSP is in contact with the substrate RP, the top surface R-UF of the substrate RP and the first and third sub-surfaces SF1 and SF3 of the support SSP-1 may define an accommodation space in which the resin composition RC (see FIG. 9C) is provided. The resin composition RC (see FIG. 9C) may be provided in a liquid state, and the preliminary resin layer P-RL may be a liquid layer before the curing. The resin composition RC (see FIG. 9C) may be provided in various manners. For example, the resin composition RC may be provided by a method such as spin-coating, slot-die, ink-jet printing, spray coating, etc.

Referring to FIG. 11A, the preliminary resin layer P-RL formed from the resin composition RC (see FIG. 9C) may be disposed on an entirety of the top surface R-UF of a substrate RP. The preliminary resin layer P-RL may entirely cover the top surface R-UF of the substrate RP. In addition, at least a portion of the preliminary resin layer P-RL (e.g., the extended portion) may be disposed on the first sub-surface SF1 and the third sub-surface SF3 of the support SSP. The preliminary resin layer P-RL may cover an entirety of the third sub-surface SF3 and cover at least a portion of the first sub-surface SF1. A portion of the preliminary resin layer P-RL disposed on the top surface R-UF of the substrate RP may be referred to as a first resin portion, a portion of the preliminary resin layer P-RL disposed on the first sub-surface SF1 of the support SSP may be referred to as a second resin portion, and a portion disposed on the third sub-surface SF3 may be referred to as a third resin portion.

Prior to the providing the heat HT to the preliminary resin layer P-RL, the preliminary resin layer P-RL may have a shape in which the top surface PR-UF is wider than the lower surface PR-LF along a planar direction (e.g., in a direction along the substrate RP). As a portion of the preliminary resin layer P-RL is in contact with the first sub-surface SF1 of the support SSP which is inclined at a predetermined angle, an area of the top surface PR-UF of the preliminary resin layer P-RL may be greater than that of the lower surface PR-LF of the preliminary resin layer P-RL. For example, as illustrated in FIG. 11A, the preliminary resin layer P-RL may have an inverse trapezoidal shape in which the top surface PR-UF is wider than the lower surface PR-LF.

Referring to FIG. 11B, the providing the heat HT from the support SSP-1 to the preliminary resin layer P-RL may be performed. The support SSP-1 may be heated by operating the heater (not shown). For example, the heater (not shown) may be installed inside the support SSP-1 and may operate to heat the support SSP-1 after the preliminary resin layer P-RL is applied on the substrate RP. Here, the heater (not shown) may be provided with a driving part to selectively generate heat only after the preliminary resin layer P-RL is applied on the substrate RP.

In the method for manufacturing the display device DD according to an embodiment illustrated in FIGS. 11A to 11C, the heater (not shown) may be installed inside the support SSP-1, and the support SSP-1 may be selectively heated, but the embodiment is not limited thereto. The heater (not shown) may be installed in a separate device (not shown) which accommodates and drives a heating device of the heater (not shown) to transfer heat to the support SSP-1. In this case, the support SSP-I may be provided by being heated in advance in the preparing the support SSP-1, and the forming the preliminary resin layer P-RL and the providing the heat to the preliminary resin layer P-RL may be performed at the same time.

When the support SSP-1 is heated, the heat may be transferred from the support SSP-1 to the preliminary resin layer P-RL. In the providing the heat from the support SSP-1 to the preliminary resin layer P-RL, the second and third resin portions of the preliminary resin layer P-RL which is in contact with the support SSP-1 may be heated. A portion of the preliminary resin layer P-RL which is in contact with the first sub-surface SF1 and the third sub-surface SF3 of the support SSP-1 may be heated to a higher temperature compared to a portion which is not in contact with the first sub-surface SF1 and the third sub-surface SF3 of the support SSP-1. Since the surface tension of the portion which is in contact with the first sub-surface SF1 and the third sub-surface SF3 in the preliminary resin layer P-RL is reduced, at least a portion of the portion which is in contact with the first sub-surface SF1 and the third sub-surface SF3 may move from the support SSP-1 toward the central portion of the substrate RP.

The second resin portion disposed on the first portion SP1 and the third resin portion disposed on the third portion SP3 in the preliminary resin layer P-RL may be heated to a higher temperature than the first resin portion disposed on the top surface R-UF of the substrate RP. Thus, since the surface tension of each of the second and third resin portions is reduced, at least a portion of each of the second and third resin portions may move from the support SSP-1 toward the central portion of the substrate RP. The temperature difference between the first resin portion, the second resin portion, and the third resin portion, which are formed in the providing the heat HT from the support SSP-1 to the preliminary resin layer P-RL is not particularly limited as long as it may cause a flow of the preliminary resin layer P-RL, but may be, for example, about 10° C. or more.

Referring to FIGS. 11A and 11B together, when an area on which the preliminary resin layer P-RL is contact with the first and third sub-surfaces SF1 and SF3 before the providing the heat HT to the preliminary resin layer P-RL is defined as a third contact area, and an area on which the preliminary resin layer P-RL is in contact the first and third sub-surfaces SF1 and SF3 after the providing the heat HT to the preliminary resin layer P-RL is defined as a fourth contact area, the fourth contact area may be less than the third contact area.

In the providing the heat HT to the preliminary resin layer P-RL, as at least a portion of the preliminary resin layer P-RL which is in contact with the first and third sub-surfaces SF1 and SF3 moves toward the central portion of the substrate RP, the planar area of the preliminary resin layer P-RL which is in contact with the first and third sub-surfaces SF1 and SF3 may be reduced.

Referring to FIG. 11C, the preliminary resin layer P-RL may be cured to form the resin layer AP. After the providing the heat HT to the preliminary resin layer P-RL from the support SSP-1, the curing the preliminary resin layer P-RL may be performed. At least a portion of the preliminary resin layer P-RL which is in contact with the first and third sub-surfaces SF1 and SF3 may be heated by the heat HT to move toward the central portion of the substrate RP, and thus, the preliminary resin layer P-RL may be cured to form the resin layer AP. That is, at least a portion of the preliminary resin layer P-RL which is in contact with the first and third sub-surfaces SF1 and SF3 may move toward the central portion of the substrate RP through the Marangoni flow phenomenon, and then, the shape of the preliminary resin layer P-RL may be fixed by photo-curing the preliminary resin layer P-RL. Light LT may be irradiated to the entire surface of the preliminary resin layer P-RL, and the preliminary resin layer P-RL including a photoinitiator may be cured by the light LT. For example, the preliminary resin layer P-RL may be cured by UV light.

The preliminary resin layer P-RL may be cured to form the resin layer AP as illustrated in FIG. 9G. Although not shown, after the preliminary resin layer P-RL is cured, and the resin layer AP is formed, the support SSP-1 may be separated from the substrate RP on which the resin layer AP (see FIG. 9G) is formed.

If the finally-formed resin layer is thin, or the adhesion between the finally-formed resin layer and the substrate RP is weak, excessive shrinkage may occur in the lower portion of the resin layer AP during the curing. Here, the excessive shrinkage of the lower part of the resin layer AP may cause an uncoated area to appear at the edge of the substrate RP, resulting in defects in the display device DD. In an embodiment of the invention, since the support SSP further includes a flat part extending toward the inside of the support SSP from the inclined part, the excessive shrinkage of the lower portion of the resin layer AP may be compensated to prevent the occurrence of the above-mentioned uncoated area. Therefore, the durability and reliability of the display device DD may be improved.

In the method for manufacturing the display device DD according to the embodiment of the invention, the convection due to the Marangoni phenomenon may be induced at the edge portion by using the support SSP having the predetermined inclined surface to form the resin layer AP having the improved uniformity. Thus, the display device DD having the improved reliability and durability characteristics may be provided.

The apparatus for manufacturing (or providing) the display device DD according to the embodiment of the invention may include a support frame (e.g., the support SSP) in which the opening OP, in which the target substrate is disposed, is defined. The support frame may further include the inclined part where a thickness of the support frame gradually increases toward the outside edge thereof, to improve the efficiency of the process of manufacturing the display device DD. Thus, the display device DD including the resin layer AP having the homogeneous thin film characteristics may be provided.

The display devices DD, DD-1 and DD-2 according to embodiments of the present disclosure may be applied to various electronic devices. An electronic device according to an embodiment of the present disclosure may further include a module or device having additional functions in addition to the display device DD, DD-1 or DD-2.

FIG. 12 is a block diagram illustrating an electronic device according to an embodiment of the present disclosure.

Referring to FIG. 12, an electronic device 1000 may include a display module 1010 (e.g., the display module DM), a processor 1020, a memory 1030, and a power module 1040.

The processor 1020 may include at least one of a central processing unit (CPU), an application processor (AP), a graphic processing unit (GPU), a communication processor (CP), an image signal processor (ISP), and a controller.

The memory 1030 may store data information necessary for an operation of the processor 1020 or the display module 1010. When the processor 1020 executes an application stored in the memory 1030, an image data signal and/or an input control signal may be transmitted to the display module 1010, and the display module 1010 may process the received signal and output image information through a display screen.

The power module 1040 may include a power supply module such as a power adapter, a battery device, or the like and a power conversion module which converts power supplied by the power supply module to generate power necessary for an operation of the electronic device 1000.

At least one of the components of the electronic device 1000 described above may be included in the display device DD, DD-1 or DD-2 according to embodiments described above. In addition, some of individual modules functionally included in one module may be included in the display device DD, and others may be provided separately from the display device DD. For example, the display device DD may include the display module 1010, and the processor 1020, the memory 1030, and the power module 1040 may be provided in form of other devices in the electronic device 1000 other than the display device.

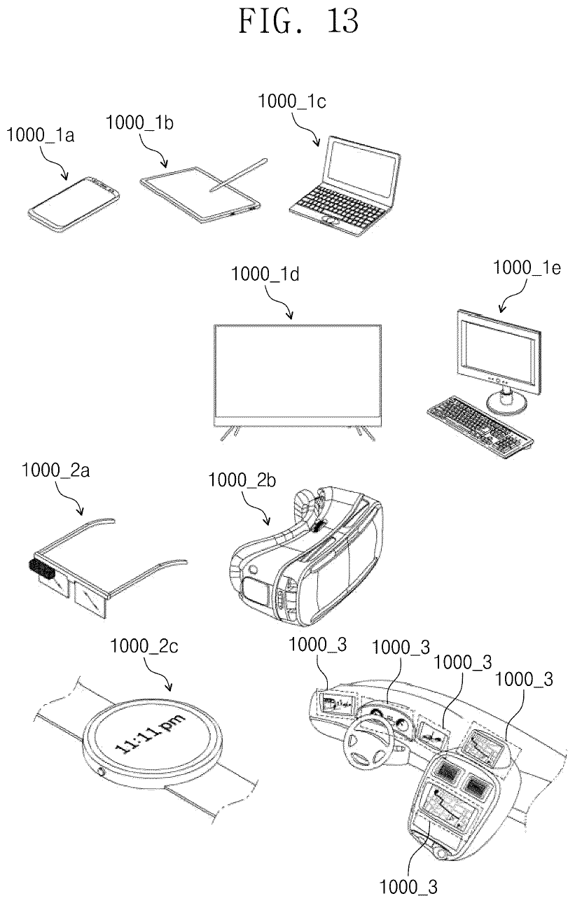

FIG. 13 is a schematic view of electronic devices according to embodiments of the present disclosure.

Referring to FIG. 13, various electronic devices to which the display device DD, DD-1 or DD-2 according to embodiments of the present disclosure are applied may include not only an image display electronic device, but also a wearable electronic device including a display module, a vehicle electronic device 1000_3 including a display module, or the like. The image display electronic device may be a smartphone 1000_1a, a tablet PC 1000_1b, a laptop 1000_1c, a TV 1000_1d, a desk monitor 1000_1c, or the like. The wearable electronic device may be smart glasses 1000_2a, a head mounted display 1000_2b, a smart watch 1000_2c, or the like. The vehicle electronic device 1000_3 may be a center information display (CID) disposed on a dashboard and center fascia of a vehicle, a room mirror display, or the like.

In an embodiment, a method for providing an electronic device includes providing a substrate RP of a display device DD, the substrate RP including a top surface, a bottom surface which is opposite to the top surface, and an outer side surface connecting the top surface to the bottom surface, providing a support frame (e.g., the support SSP) to surround the outer side surface of the substrate, the support frame including a top surface including a first sub-surface inclined at an angle with respect to the top surface of the substrate, providing a resin material (e.g., resin composition RC) on the top surface of the substrate, the resin material extending from the top surface of the substrate and along the first sub-surface of the support frame to define a preliminary resin layer P-RL on the substrate, providing heat HT from the support frame to the preliminary resin layer on the substrate, curing the preliminary resin layer on the substrate to form a resin layer AP of the display device DD which is on the substrate; and separating the support frame from the substrate having the resin layer thereon.

The angle may be greater than or equal to about 20 degrees and less than or equal to about 85 degrees.

The top surface of the support frame may further include a second sub-surface parallel to the top surface of the substrate, a first thickness portion which is adjacent to the outer side surface of the substrate in a first direction and defines the first sub-surface, and a second thickness portion which is spaced apart from the outer side surface of the substrate in the first direction with the first thickness portion therebetween and defines the second sub-surface.

The first thickness portion and the second thickness portion portion may provide a single body of the support frame.

The support frame may further include an inner side surface which extends from the first sub-surface and defines an opening of the support frame, and the providing of the support frame may include the substrate within the opening and the outer side surface of the substrate facing the inner side surface of the support frame.

The providing of the support frame may further include contacting the inner side surface of the support frame with the outer side surface of the substrate.

The providing of the resin material may include providing the preliminary resin layer in contact with the first sub-surface of the support frame, and in the providing of the heat from the support frame to the preliminary resin layer on the substrate, a portion of the preliminary resin layer which is in contact with the first sub-surface moves from the first sub-surface of the support frame and toward a central portion of the substrate.

The providing of the resin material may define a first contact area between the preliminary resin layer and the first sub-surface of the support frame, and the providing of the heat from the support frame to the preliminary resin layer on the substrate may define a second contact area between the preliminary resin layer and the first sub-surface which is less than the first contact area.

The support frame may further include a metal material, and at least the first

The support frame may further include a hydrophobic material. sub-surface being hydrophobic.

The support frame may further include the top surface of the support frame further including a second sub-surface and a third sub-surface each parallel to the top surface of the substrate, a first thickness portion defining the first sub-surface, a second thickness portion which is further from the outer side surface of the substrate than the first thickness portion and defines the second sub-surface, and a third thickness portion between the first thickness portion and the substrate and defining the third sub-surface. The providing of the resin material may further include providing the preliminary resin layer in contact with each of the first sub-surface and the third sub-surface. Within the support frame, at least the first sub-surface and the third sub-surface may be hydrophobic.

The support frame may further include an inner side surface which extends from the third sub-surface, and the providing of the support frame may further include providing the outer side surface of the substrate in contact with the inner side surface of the support frame.

The providing of the support frame may include the third sub-surface being coplanar with the top surface of the substrate.

The outer side surface of the substrate may further include side surfaces each connecting the top surface of the substrate to the bottom surface of the substrate, where the side surfaces include a first side surface and a second side surface which face each other along a first direction, and a third side surface and a fourth side surface which face each other along a second direction crossing the first direction. The support frame may include sub-supports assembled with each other to define the support frame. The providing of the support frame may include disposing among the sub-supports a first sub-support in contact with the first side surface, a second sub-support in contact with the second side surface, a third sub-support in contact with the third side surface, and a fourth sub-support in contact with the fourth side surface.

The support frame may further include the top surface of the support frame further including a second sub-surface parallel to the top surface of the substrate, and each of the first to fourth sub-supports including a first thickness portion adjacent to the outer side surface of the substrate and defining the first sub-surface, and a second thickness portion which is spaced apart from the outer side surface of the substrate with the first thickness portion therebetween and defines the second sub-surface.

In an embodiment, a method for providing an electronic device may include providing a substrate of a display device, the substrate including a top surface, a bottom surface which is opposite to the top surface, and an outer side surface connecting the top surface to the bottom surface, providing a support frame in contact with the outer side surface of the substrate, the support frame including an inclined top surface along which a thickness of the support frame increases in a direction away from the outer side surface of the substrate, providing a resin material on the substrate and extended from the substrate along the inclined top surface of the support frame to define a preliminary resin layer on the substrate, providing heat from the support frame to the preliminary resin layer on the substrate, curing the preliminary resin layer on the substrate to form a resin layer of the display device which is on the substrate, and separating the support frame from the substrate having the resin layer thereon.

The support frame may further include a flat top surface which is between the outer side surface of the substrate and the inclined top surface and is coplanar with the top surface of the substrate, the support frame having a constant thickness along the flat top surface.

An apparatus for providing an electronic device includes a stage on which a substrate of a display device is provided, the substrate including a top surface, a bottom surface facing the stage, and an outer side surface connecting the top surface to the bottom surface, a support frame in which an opening is defined and in which the substrate is accommodated, the support frame including an inclined top surface along which a thickness of the support frame increases in a direction away from the opening, and a heater configured to provide heat to the support frame having the substrate accommodated within the opening. The apparatus having the substrate accommodated within the opening of the support frame includes the inclined top surface of the support frame extending inclined from the top surface of the substrate and in a direction away from the stage.

It will be apparent to those skilled in the art that various modifications and variations may be made in the invention. Thus, it is intended that the present disclosure covers the modifications and variations of this invention provided they come within the scope of the appended claims and their equivalents. Hence, the real protective scope of the invention shall be determined by the technical scope of the accompanying claims.

What is claimed is:

1. A method for providing an electronic device, the method comprising:
providing a substrate of a display device, the substrate comprising a top surface, a bottom surface which is opposite to the top surface, and an outer side surface connecting the top surface to the bottom surface;
providing a support frame to surround the outer side surface of the substrate, the support frame comprising a top surface including a first sub-surface inclined at an angle with respect to the top surface of the substrate;
providing a resin material on the top surface of the substrate, the resin material extending from the top surface of the substrate and along the first sub-surface of the support frame to define a preliminary resin layer on the substrate;
providing heat from the support frame to the preliminary resin layer on the substrate;
curing the preliminary resin layer on the substrate to form a resin layer of the display device which is on the substrate; and
separating the support frame from the substrate having the resin layer thereon.

2. The method of claim 1, wherein the support frame further comprises:
the top surface of the support frame further including a second sub-surface parallel to the top surface of the substrate,
a first thickness portion which is adjacent to the outer side surface of the substrate in a first direction and defines the first sub-surface; and
a second thickness portion which is spaced apart from the outer side surface of the substrate in the first direction with the first thickness portion therebetween and defines the second sub-surface.

3. The method of claim 2, wherein the first thickness portion and the second thickness portion portion provide a single body of the support frame.

4. The method of claim 1, wherein
the support frame further comprises an inner side surface which extends from the first sub-surface and defines an opening of the support frame; and
the providing of the support frame comprises the substrate within the opening and the outer side surface of the substrate facing the inner side surface of the support frame.

5. The method of claim 4, wherein the providing of the support frame further comprises contacting the inner side surface of the support frame with the outer side surface of the substrate.

6. The method of claim 1, wherein
the providing of the resin material comprises providing the preliminary resin layer in contact with the first sub-surface of the support frame, and
in the providing of the heat from the support frame to the preliminary resin layer on the substrate, a portion of the preliminary resin layer which is in contact with the first sub-surface moves from the first sub-surface of the support frame and toward a central portion of the substrate.

7. The method of claim 1, wherein
the providing of the resin material defines a first contact area between the preliminary resin layer and the first sub-surface of the support frame, and
the providing of the heat from the support frame to the preliminary resin layer on the substrate defines a second contact area between the preliminary resin layer and the first sub-surface which is less than the first contact area.

8. The method of claim 1, wherein the angle is greater than or equal to about 20 degrees and less than or equal to about 85 degrees.

9. The method of claim 1, wherein the support frame further comprises a hydrophobic material.

10. The method of claim 1, wherein the support frame further comprises:
a metal material, and
at least the first sub-surface being hydrophobic.

11. The method of claim 1, wherein the support frame further comprises:
the top surface of the support frame further including a second sub-surface and a third sub-surface each parallel to the top surface of the substrate;
a first thickness portion defining the first sub-surface;
a second thickness portion which is further from the outer side surface of the substrate than the first thickness portion and defines the second sub-surface; and
a third thickness portion between the first thickness portion and the substrate and defining the third sub-surface.

12. The method of claim 11, wherein the providing of the resin material comprises providing the preliminary resin layer in contact with each of the first sub-surface and the third sub-surface.

13. The method of claim 11, wherein within the support frame, at least the first sub-surface and the third sub-surface are hydrophobic.

14. The method of claim 11, wherein
the support frame further comprises an inner side surface which extends from the third sub-surface, and
the providing of the support frame comprises providing the outer side surface of the substrate in contact with the inner side surface of the support frame.

15. The method of claim 11, wherein the providing of the support frame comprises the third sub-surface being coplanar with the top surface of the substrate.

16. The method of claim 1, wherein
the outer side surface of the substrate comprises side surfaces each connecting the top surface of the substrate to the bottom surface of the substrate, the side surfaces comprising:
a first side surface and a second side surface which face each other along a first direction, and
a third side surface and a fourth side surface which face each other along a second direction crossing the first direction,
the support frame comprises sub-supports assembled with each other to define the support frame; and
the providing of the support frame comprises disposing among the sub-supports:
a first sub-support in contact with the first side surface;
a second sub-support in contact with the second side surface;
a third sub-support in contact with the third side surface; and
a fourth sub-support in contact with the fourth side surface.

17. The method of claim 16, wherein the support frame further comprises:
the top surface of the support frame further including a second sub-surface parallel to the top surface of the substrate; and
each of the first to fourth sub-supports comprising:
a first thickness portion adjacent to the outer side surface of the substrate and defining the first sub-surface; and
a second thickness portion which is spaced apart from the outer side surface of the substrate with the first thickness portion therebetween and defines the second sub-surface.

18. A method for providing an electronic device, the method comprising:
providing a substrate of a display device, the substrate comprising a top surface, a bottom surface which is opposite to the top surface, and an outer side surface connecting the top surface to the bottom surface;
providing a support frame in contact with the outer side surface of the substrate, the support frame comprising an inclined top surface along which a thickness of the support frame increases in a direction away from the outer side surface of the substrate;
providing a resin material on the substrate and extended from the substrate along the inclined top surface of the support frame to define a preliminary resin layer on the substrate;
providing heat from the support frame to the preliminary resin layer on the substrate;
curing the preliminary resin layer on the substrate to form a resin layer of the display device which is on the substrate; and
separating the support frame from the substrate having the resin layer thereon.

19. The method of claim 18, wherein the support frame further comprises a flat top surface which is between the outer side surface of the substrate and the inclined top surface and is coplanar with the top surface of the substrate, the support frame having a constant thickness along the flat top surface.

20. An apparatus for providing an electronic device, the apparatus comprising:
a stage on which a substrate of a display device is provided, the substrate comprising a top surface, a bottom surface facing the stage, and an outer side surface connecting the top surface to the bottom surface;
a support frame in which an opening is defined and in which the substrate is accommodated, the support frame comprising an inclined top surface along which a thickness of the support frame increases in a direction away from the opening; and
a heater configured to provide heat to the support frame having the substrate accommodated within the opening,
wherein the apparatus having the substrate accommodated within the opening of the support frame includes the inclined top surface of the support frame extending inclined from the top surface of the substrate and in a direction away from the stage.
